(19) United States
(12) Patent Application Publication
(10) Pub. No.: US 2026/0095126 A1
(43) Pub. Date: Apr. 2, 2026

(54) SPACE EFFICIENT POWER OVER ETHERNET FOR AUDIO PLAYBACK DEVICES

(71) Applicant: Sonos, Inc., Goleta, CA (US)

(72) Inventor: Mark Gerlovin, Brookline, MA (US)

(21) Appl. No.: 19/112,649

(22) PCT Filed: Sep. 18, 2023
(86) PCT No.: PCT/US2023/074437

§ 371 Date: Mar. 18, 2025

Related U.S. Application Data
(60) Provisional application No. 63/376,116, filed on Sep. 19, 2022.

(51) Int. Cl. H03F 1/30; H03F 3/183; H04L 12/10

(52) U.S. Cl. CPC H03F 1/30; H03F 3/183; H04L 12/10

(57) ABSTRACT

Examples include audio playback devices having power supply circuitry that is configured to condition power received over, for example, an Ethernet or USB connection, to provide steady power to an output device such as a speaker, and methods of operating such audio playback devices.

### CROSS-REFERENCE TO RELATED APPLICATIONS

This application claims priority under 35 U.S.C § 119(e), PCT Article 8, and Article 4 of the Paris Convention to co-pending U.S. Provisional Patent Application No. 63/376,116 filed on Sep. 19, 2022 and titled “SPACE EFFICIENT POWER OVER ETHERNET FOR AUDIO PLAYBACK DEVICES,” which is hereby incorporated herein by reference in its entirety for all purposes.

### FIELD OF THE DISCLOSURE

The present disclosure is related to consumer goods and, more particularly, to methods, systems, products, features, services, and other elements directed to media playback or some aspect thereof.

### BACKGROUND

Options for accessing and listening to digital audio in an out-loud setting were limited until in 2002, when Sonos, Inc. began development of a new type of playback system. Sonos then filed one of its first patent applications in 2003, entitled “Method for Synchronizing Audio Playback between Multiple Networked Devices,” and began offering its first media playback systems for sale in 2005. The SONOS Wireless Home Sound System enables people to experience music from many sources via one or more networked playback devices. Through a software control application installed on a controller (e.g., smartphone, tablet, computer, voice input device), one can play what she wants in any room having a networked playback device. Media content (e.g., songs, podcasts, video sound) can be streamed to playback devices such that each room with a playback device can play back corresponding different media content. In addition, rooms can be grouped together for synchronous playback of the same media content, and/or the same media content can be heard in all rooms synchronously.

### BRIEF DESCRIPTION OF THE DRAWINGS

Features, aspects, and advantages of the presently disclosed technology may be better understood with regard to the following description, appended claims, and accompanying drawings, as listed below. A person skilled in the relevant art will understand that the features shown in the drawings are for purposes of illustrations, and variations, including different and/or additional features and arrangements thereof, are possible.

FIG. 1A is a partial cutaway view of an environment having a media playback system configured in accordance with aspects of the disclosed technology.

FIG. 1B is a schematic diagram of the media playback system of FIG. 1A and one or more networks.

FIG. 1C is a block diagram of a playback device.

FIG. 1D is a block diagram of a playback device.

FIG. 1E is a block diagram of a bonded playback device.

FIG. 1F is a block diagram of a network microphone device.

FIG. 1G is a block diagram of a playback device.

FIG. 1H is a partial schematic diagram of a control device.

FIG. 2 is a schematic diagram of a sample playback device including power supply circuitry configured to condition received power for audio playback, in accordance with at least one embodiment of the present disclosure.

FIGS. 3A and 3B are examples of schematics of sample playback devices configured to receive various input power, in accordance with at least one embodiment disclosed herein.

FIGS. 4A-4E are examples of schematics of various power supply circuitry examples to be included in a playback device, in accordance with at least one embodiment disclosed herein.

FIG. 5 is a sample graph showing the output of a simulation of power supply circuitry as described herein, in accordance with at least one embodiment disclosed herein.

FIG. 6 is a schematic diagram of one example of the circuitry of FIG. 4B, in accordance with at least one embodiment disclosed herein.

FIGS. 7A and 7B are circuit diagrams for one example of a portion of the circuitry of FIG. 6, in accordance with at least one embodiment disclosed herein.

FIG. 8 is a circuit diagram for one example of another portion of the circuitry of FIG. 6, in accordance with at least one embodiment disclosed herein.

The drawings are for the purpose of illustrating example embodiments, but those of ordinary skill in the art will understand that the technology disclosed herein is not limited to the arrangements and/or instrumentality shown in the drawings.

### DETAILED DESCRIPTION

### I. Overview

Embodiments described herein relate to using available Power over Ethernet (PoE) to power audio playback devices while minimizing the overall size of the audio playback devices. Typical audio playback devices such as a smart speaker that is configured to both process and output a digital audio stream are generally configured to be powered directly by an Alternating Current (AC) power source such as a power cord providing 110 volt-230 volt AC power. Such an example is typical in the consumer audio space. However, many businesses having commercial and/or industrial spaces such as warehouses also wish to fill the space with audio. Typically, commercial establishments mount audio playback devices to walls and/or ceilings and run both Ethernet and AC power to each of the playback devices. Accordingly, it would be advantageous to add support for PoE to playback devices such that only one Ethernet cable needs to be run to each playback device instead of both an Ethernet cable and a separate power cable. As such, adding PoE support can lower the barrier to deploying a large number of playback devices in a commercial setting such as a warehouse.

However, such an arrangement has various drawbacks. For example, a playback device may have significant peak power demands during certain playback situations (e.g., at high volume for certain audio tracks) that considerably exceed the capabilities of many PoE systems. For instance, the peak power demand of an audio playback device may be 120 watts while the most common PoE types (PoE and PoE+) only support up to 15 to 30 watts (e.g., PoE supports up to ˜15 watts and PoE+ supports ˜30 watts). Accordingly, a typical PoE design suitable for devices with relatively consistent power demands would result in undesirable audio distortion during audio playback.

A straightforward solution could be to simply add bulk capacitors to the supply rail for the audio amplifier of the playback device. The problem with such a solution is that the supply rail voltage (and the voltage across the capacitors) cannot vary much without introducing distortion into the audio output. For instance, the audio amplifier may introduce audio clipping distortion when the supply rail voltage drops too low. Given that the energy stored in a capacitor increases with a square of the voltage across the capacitor, the usable energy stored in the capacitor (e.g., the energy that can be discharged without the supply rail voltage dropping too low) is quite small. The formula for calculating the energy stored in a capacitor is shown below as Function (F1), where E is the energy stored, V is the voltage across the capacitor, and C is the capacitance of the capacitor.

$$E = \frac{1}{2} * C * {V}^{2} \qquad ( F1 )$$

Given the relationship between voltage and energy stored, the bulk capacitors would have to be quite large in size and/or quantity in order to achieve the high capacitance required to provide a sufficient amount of usable energy. The usable energy in the capacitor is represented by Function (F2) below, where Eₘₐₓ is the amount of energy in the capacitor when the voltage is at the maximum value, Eₘᵢₙ is the amount of energy in the capacitor when the voltage is at the minimum value, and E_{usable} is a percentage of Eₘₐₓ that can be used without going below the minimum voltage. Function (F3) rewrites Function (F2) in terms of the maximum voltage across the capacitor (Vₘₐₓ) and the minimum voltage across the capacitor (Vₘᵢₙ).

$${E}_{u s a b l e} = \frac{{E}_{max} - {E}_{min}}{{E}_{max}} \qquad ( F2 )$$

$${E}_{u s a b l e} = \frac{{V}_{max}^{2} - {V}_{min}^{2}}{{V}_{max}^{2}} \qquad ( F3$$

In a situation where the bulk capacitors are simply added to the supply rail, the supply rail voltage may only be able to deviate by a few volts before risking the introduction of audio distortion. For instance, the supply rail voltage may be 24 volts and the supply rail voltage may be allowed to drop by only 2 volts without creating a significant risk of audio distortion. Working those values for the maximum voltage (24 Volts) and the minimum voltage (22 Volts) through Function (F3), the usable energy in the capacitors is only about 16%. As a result, the total capacitance of the bulk capacitors would need to be quite high to achieve a meaningful amount of energy storage. Such a large total capacitance would require a significant amount of physical space to achieve that is undesirable given the typical constraints within a playback device. For instance, a playback device may have volume constraints to fit into a specific form factor (e.g., to fit in a specific type of fixture). Additionally, playback devices typically have a minimum acoustic volume that is required for the playback device to achieve the desired acoustic performance. Given such acoustic volume requirements, an increase in the size of any internal components would require an undesirable increase in the overall size of the playback device so as to maintain acoustic volume.

Aspects of the present disclosure provide an architecture that increases the amount of usable power in the capacitors by leveraging the voltage difference between the high DC voltage output by a front-end circuit (e.g., approximately 50 volts in a typical PoE implementation) and the lower DC voltage as needed to operate the operational amplifier of the playback device (e.g., about 24 volts). In such an architecture, the build capacitor(s) are charged the high DC voltage output by the front-end circuit and allowed to discharge down to a lower DC voltage that is needed to operate the amplifier (and/or operate a DC/DC converter that outputs the supply rail voltage). Additionally, a limiter circuit (e.g., a current limiter circuit) may be placed between the front-end circuit and the build capacitor(s) to help ensure that the power limits (e.g., current limits, voltage limits, etc.) of the front-end circuit are not exceeded while discharging the capacitor (e.g., during a scenario when the power demand exceeds the capability of the front-end circuit). As a result, the voltage across the bulk capacitor(s) can vary across a much wider range that substantially increases the usable energy that can be discharged from the bulk capacitor(s). Accordingly, significantly smaller capacitor(s) can be used to achieve the same usable energy while maintaining audio output performance that is comparable with that provided by playback devices powered by AC power. For example, the voltage across the bulk capacitor(s) may be allowed to vary between 50 volts (e.g., voltage output by a typical PoE front-end circuit) and 24 volts (e.g., a typical supply rail voltage for an amplifier). Working those values for the maximum voltage (50 Volts) and the minimum voltage (24 Volts) through Function (F3), the usable energy in the capacitors is very high at about 77%. Accordingly, the total capacitance value of the bulk capacitor(s) can be significantly lower (and the corresponding physical volume requirements significantly smaller) than conventional solutions.

In some embodiments, for example, a playback device can include power supply circuitry that is configured to condition power received over, for example, an Ethernet or USB connection, to provide steady power to an output device such as a speaker. The playback device can include at least one powered communication port configured to receive audio data and line power, the line power being limited to a maximum power and a maximum current. The playback device may further include one or more amplifiers configured to drive one or more speakers, the one or more amplifiers being operable to consume conditioned power and having a peak power consumption that is greater than the maximum power of the line power. The playback device may further include power supply circuitry comprising at least one capacitor, the power supply circuitry configured to receive the line power, charge the at least one capacitor to store energy, supply the conditioned power at least in part by discharging 50% or more of the energy stored in the at least one capacitor, and limit a current draw of the power supply circuitry to a level that is no more than the maximum current of the line power. In addition, the playback device may include at least one communication interface configured to facilitate communication via the at least one powered communication port, at least one processor coupled to the at least one network interface and the one or more amplifiers, and at least one non-transitory computer-readable medium coupled to the at least one processor and storing program instructions executable by the at least one processor to control the playback device to play back at least a portion of the audio data, wherein to play back comprises to supply the one or more amplifiers with the conditioned power based on the portion of the audio data.

In some embodiments, the playback device may be implemented as a stationary playback device that requires a connection to an external power source (e.g., a PoE injector, a USB adapter, etc.) in order to playback an audio track. For instance, the stationary playback device may not be capable of using any internal energy storage device(s) (e.g., a battery) to playback an audio track when not connected to an external power source.

In some embodiments, the playback device may not be capable of directly receiving mains AC power (e.g., AC power from a wall outlet between 110 and 230 volts) as a power input. For instance, the playback device may only receive power through other power sources separate and apart from mains AC power such as one or more of the following: PoE power sources, USB power sources, and/or wireless power sources such as QI wireless transmitters.

While some examples described herein may refer to functions performed by given actors such as “users,” “listeners,” and/or other entities, it should be understood that such references are for purposes of explanation only. The claims should not be interpreted to require action by any such example actor unless explicitly required by the language of the claims themselves.

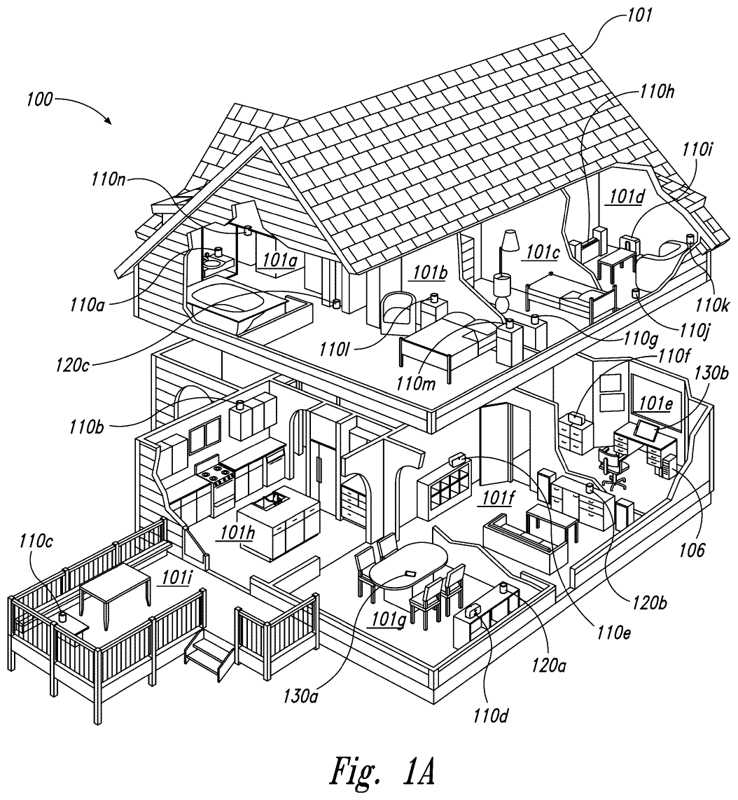

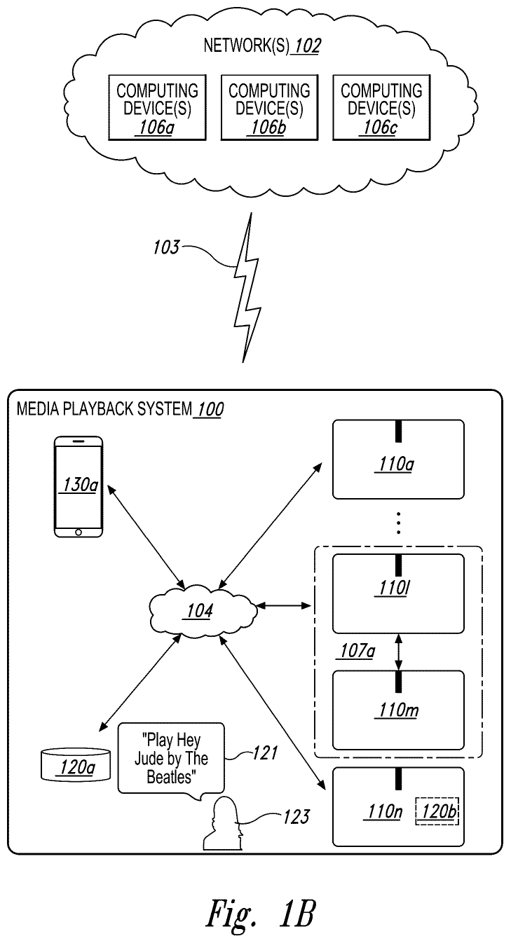

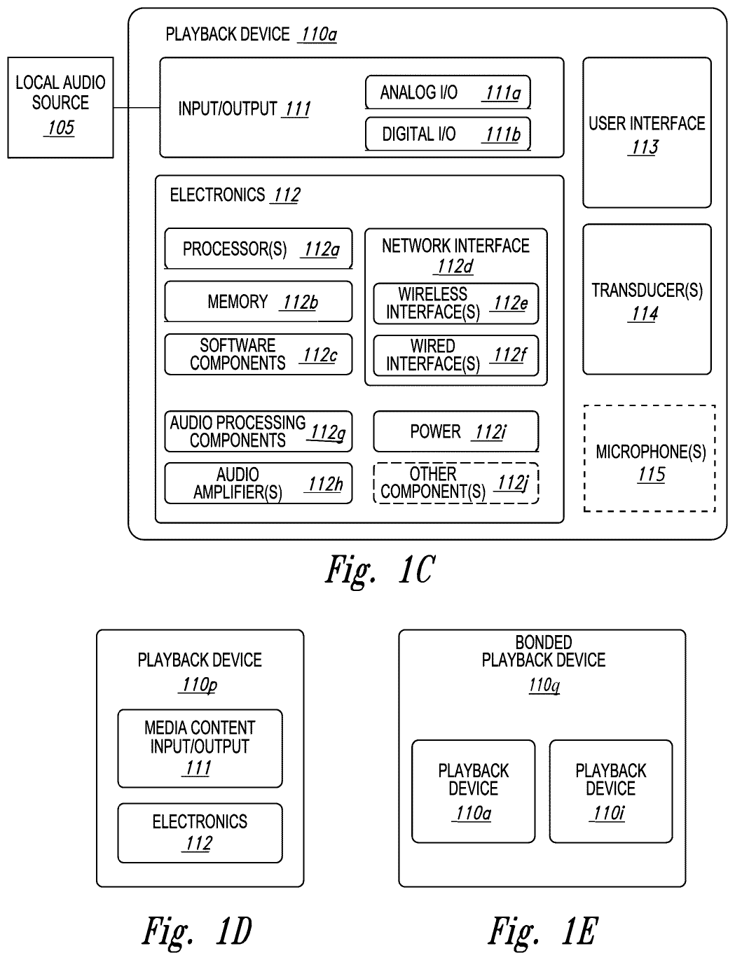

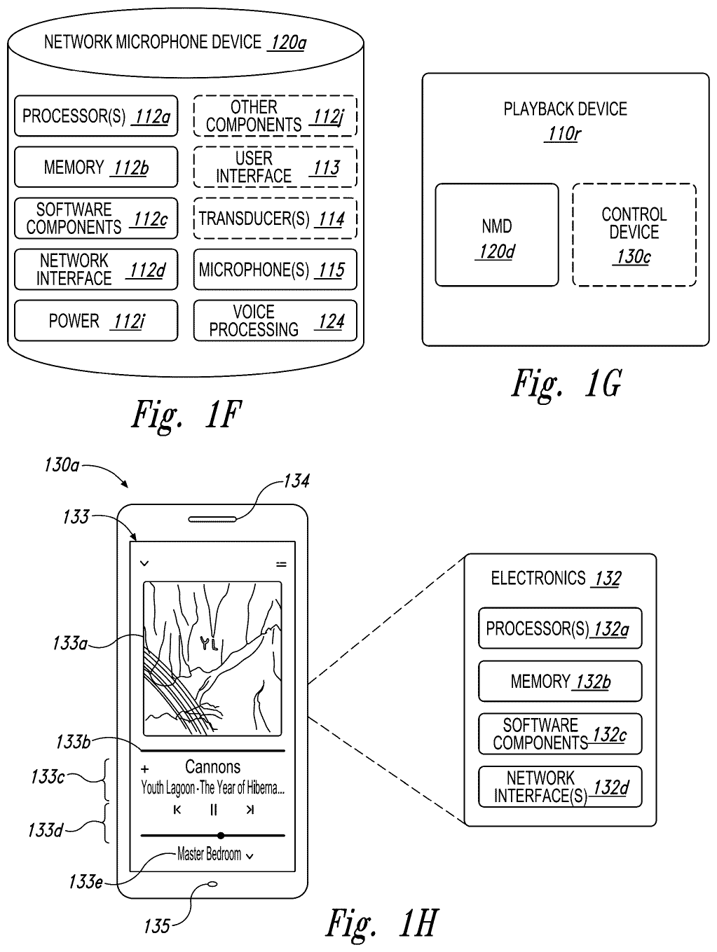

In the Figures, identical reference numbers identify generally similar, and/or identical, elements. To facilitate the discussion of any particular element, the most significant digit or digits of a reference number refers to the Figure in which that element is first introduced. For example, element 110a is first introduced and discussed with reference to FIG. 1A. Many of the details, dimensions, angles and other features shown in the Figures are merely illustrative of particular embodiments of the disclosed technology. Accordingly, other embodiments can have other details, dimensions, angles and features without departing from the spirit or scope of the disclosure. In addition, those of ordinary skill in the art will appreciate that further embodiments of the various disclosed technologies can be practiced without several of the details described below.

### II. Suitable Operating Environment

FIG. 1A is a partial cutaway view of a media playback system 100 distributed in an environment 101 (e.g., a house). The media playback system 100 comprises one or more playback devices 110 (identified individually as playback devices 110a-n), one or more network microphone devices 120 (“NMDs”) (identified individually as NMDs 120a-c), and one or more control devices 130 (identified individually as control devices 130a and 130b).

As used herein the term “playback device” can generally refer to a network device configured to receive, process, and output data of a media playback system. For example, a playback device can be a network device that receives and processes audio content. In some embodiments, a playback device includes one or more transducers or speakers powered by one or more amplifiers. In other embodiments, however, a playback device includes one of (or neither of) the speaker and the amplifier. For instance, a playback device can comprise one or more amplifiers configured to drive one or more speakers external to the playback device via a corresponding wire or cable.

Moreover, as used herein the term “NMD” (i.e., a “network microphone device”) can generally refer to a network device that is configured for audio detection. In some embodiments, an NMD is a stand-alone device configured primarily for audio detection. In other embodiments, an NMD is incorporated into a playback device (or vice versa).

The term “control device” can generally refer to a network device configured to perform functions relevant to facilitating user access, control, and/or configuration of the media playback system 100.

Each of the playback devices 110 is configured to receive audio signals or data from one or more media sources (e.g., one or more remote servers, one or more local devices, etc.) and play back the received audio signals or data as sound. The one or more NMDs 120 are configured to receive spoken word commands, and the one or more control devices 130 are configured to receive user input. In response to the received spoken word commands and/or user input, the media playback system 100 can play back audio via one or more of the playback devices 110. In certain embodiments, the playback devices 110 are configured to commence playback of media content in response to a trigger. For instance, one or more of the playback devices 110 can be configured to play back a morning playlist upon detection of an associated trigger condition (e.g., presence of a user in a kitchen, detection of a coffee machine operation, etc.). In some embodiments, for example, the media playback system 100 is configured to play back audio from a first playback device (e.g., the playback device 110a) in synchrony with a second playback device (e.g., the playback device 110b). Interactions between the playback devices 110, NMDs 120, and/or control devices 130 of the media playback system 100 configured in accordance with the various embodiments of the disclosure are described in greater detail below with respect to FIGS. 1B-1H.

In the illustrated embodiment of FIG. 1A, the environment 101 comprises a household having several rooms, spaces, and/or playback zones, including (clockwise from upper left) a master bathroom 101a, a master bedroom 101b, a second bedroom 101c, a family room or den 101d, an office 101e, a living room 101f, a dining room 101g, a kitchen 101h, and an outdoor patio 101i. While certain embodiments and examples are described below in the context of a home environment, the technologies described herein may be implemented in other types of environments. In some embodiments, for example, the media playback system 100 can be implemented in one or more commercial settings (e.g., a restaurant, mall, airport, hotel, a retail or other store), one or more vehicles (e.g., a sports utility vehicle, bus, car, a ship, a boat, an airplane, etc.), multiple environments (e.g., a combination of home and vehicle environments), and/or another suitable environment where multi-zone audio may be desirable.

The media playback system 100 can comprise one or more playback zones, some of which may correspond to the rooms in the environment 101. The media playback system 100 can be established with one or more playback zones, after which additional zones may be added, or removed, to form, for example, the configuration shown in FIG. 1A. Each zone may be given a name according to a different room or space such as the office 101e, master bathroom 101a, master bedroom 101b, the second bedroom 101c, kitchen 101h, dining room 101g, living room 101f, and/or the balcony 101i. In some aspects, a single playback zone may include multiple rooms or spaces. In certain aspects, a single room or space may include multiple playback zones.

In the illustrated embodiment of FIG. 1A, the second bedroom 101c, the office 101e, the living room 101f, the dining room 101g, the kitchen 101h, and the outdoor patio 101i each include one playback device 110, and the master bathroom 101a, the master bedroom 101b, and the den 101d include a plurality of playback devices 110. In the master bedroom 101b, the playback devices 110l and 110m may be configured, for example, to play back audio content in synchrony as individual ones of playback devices 110, as a bonded playback zone, as a consolidated playback device, and/or any combination thereof. Similarly, in the den 101d, the playback devices 110h-k can be configured, for instance, to play back audio content in synchrony as individual ones of playback devices 110, as one or more bonded playback devices, and/or as one or more consolidated playback devices. Additional details regarding bonded and consolidated playback devices are described below with respect to FIGS. 1B and 1E.

In some aspects, one or more of the playback zones in the environment 101 may each be playing different audio content. For instance, a user may be grilling on the patio 101i and listening to hip hop music being played by the playback device 110c while another user is preparing food in the kitchen 101h and listening to classical music played by the playback device 110b. In another example, a playback zone may play the same audio content in synchrony with another playback zone. For instance, the user may be in the office 101e listening to the playback device 110f playing back the same hip hop music being played back by playback device 110c on the patio 101i. In some aspects, the playback devices 110c and 110f play back the hip hop music in synchrony such that the user perceives that the audio content is being played seamlessly (or at least substantially seamlessly) while moving between different playback zones. Additional details regarding audio playback synchronization among playback devices and/or zones can be found, for example, in U.S. Pat. No. 8,234,395 entitled, “System and method for synchronizing operations among a plurality of independently clocked digital data processing devices,” which is incorporated herein by reference in its entirety.

a. Suitable Media Playback System

FIG. 1B is a schematic diagram of the media playback system 100 and a cloud network 102. For ease of illustration, certain devices of the media playback system 100 and the cloud network 102 are omitted from FIG. 1B. One or more communication links 103 (referred to hereinafter as “the links 103”) communicatively couple the media playback system 100 and the cloud network 102.

The links 103 can comprise, for example, one or more wired networks, one or more wireless networks, one or more wide area networks (WAN), one or more local area networks (LAN), one or more personal area networks (PAN), one or more telecommunication networks (e.g., one or more Global System for Mobiles (GSM) networks, Code Division Multiple Access (CDMA) networks, Long-Term Evolution (LTE) networks, 5G communication network networks, and/or other suitable data transmission protocol networks), etc. The cloud network 102 is configured to deliver media content (e.g., audio content, video content, photographs, social media content, etc.) to the media playback system 100 in response to a request transmitted from the media playback system 100 via the links 103. In some embodiments, the cloud network 102 is further configured to receive data (e.g., voice input data) from the media playback system 100 and correspondingly transmit commands and/or media content to the media playback system 100.

The cloud network 102 comprises computing devices 106 (identified separately as a first computing device 106a, a second computing device 106b, and a third computing device 106c). The computing devices 106 can comprise individual computers or servers, such as, for example, a media streaming service server storing audio and/or other media content, a voice service server, a social media server, a media playback system control server, etc. In some embodiments, one or more of the computing devices 106 comprise modules of a single computer or server. In certain embodiments, one or more of the computing devices 106 comprise one or more modules, computers, and/or servers. Moreover, while the cloud network 102 is described above in the context of a single cloud network, in some embodiments the cloud network 102 comprises a plurality of cloud networks comprising communicatively coupled computing devices. Furthermore, while the cloud network 102 is shown in FIG. 1B as having three of the computing devices 106, in some embodiments, the cloud network 102 comprises fewer (or more than) three computing devices 106.

The media playback system 100 is configured to receive media content from the networks 102 via the links 103. The received media content can comprise, for example, a Uniform Resource Identifier (URI) and/or a Uniform Resource Locator (URL). For instance, in some examples, the media playback system 100 can stream, download, or otherwise obtain data from a URI or a URL corresponding to the received media content. A network 104 communicatively couples the links 103 and at least a portion of the devices (e.g., one or more of the playback devices 110, NMDs 120, and/or control devices 130) of the media playback system 100. The network 104 can include, for example, a wireless network (e.g., a WIFI network, a BLUETOOTH network, a Z-WAVE network, a ZIGBEE network, and/or other suitable wireless communication protocol network) and/or a wired network (e.g., a network comprising Ethernet, Universal Serial Bus (USB), and/or another suitable wired communication). As those of ordinary skill in the art will appreciate, as used herein, “WIFI” can refer to several different communication protocols including, for example, Institute of Electrical and Electronics Engineers (IEEE) 802.11a, 802.11b, 802.11g, 802.11n, 802.11ac, 802.11ac, 802.11ad, 802.11af, 802.11ah, 802.11ai, 802.11aj, 802.11aq, 802.11ax, 802.11ay, 802.15, etc. transmitted at 2.4 Gigahertz (GHz), 5 GHz, and/or another suitable frequency.

In some embodiments, the network 104 comprises a dedicated communication network that the media playback system 100 uses to transmit messages between individual devices and/or to transmit media content to and from media content sources (e.g., one or more of the computing devices 106). In certain embodiments, the network 104 is configured to be accessible only to devices in the media playback system 100, thereby reducing interference and competition with other household devices. In other embodiments, however, the network 104 comprises an existing household or commercial facility communication network (e.g., a household or commercial facility WIFI network). In some embodiments, the links 103 and the network 104 comprise one or more of the same networks. In some aspects, for example, the links 103 and the network 104 comprise a telecommunication network (e.g., an LTE network, a 5G network, etc.). Moreover, in some embodiments, the media playback system 100 is implemented without the network 104, and devices comprising the media playback system 100 can communicate with each other, for example, via one or more direct connections, PANs, telecommunication networks, and/or other suitable communication links. The network 104 may be referred to herein as a “local communication network” to differentiate the network 104 from the cloud network 102 that couples the media playback system 100 to remote devices, such as cloud servers that host cloud services.

In some embodiments, audio content sources may be regularly added or removed from the media playback system 100. In some embodiments, for example, the media playback system 100 performs an indexing of media items when one or more media content sources are updated, added to, and/or removed from the media playback system 100. The media playback system 100 can scan identifiable media items in some or all folders and/or directories accessible to the playback devices 110, and generate or update a media content database comprising metadata (e.g., title, artist, album, track length, etc.) and other associated information (e.g., URIs, URLs, etc.) for each identifiable media item found. In some embodiments, for example, the media content database is stored on one or more of the playback devices 110, network microphone devices 120, and/or control devices 130.

In the illustrated embodiment of FIG. 1B, the playback devices 110l and 110m comprise a group 107a. The playback devices 110l and 110m can be positioned in different rooms and be grouped together in the group 107a on a temporary or permanent basis based on user input received at the control device 130a and/or another control device 130 in the media playback system 100. When arranged in the group 107a, the playback devices 110l and 110m can be configured to play back the same or similar audio content in synchrony from one or more audio content sources. In certain embodiments, for example, the group 107a comprises a bonded zone in which the playback devices 110l and 110m comprise left audio and right audio channels, respectively, of multi-channel audio content, thereby producing or enhancing a stereo effect of the audio content. In some embodiments, the group 107a includes additional playback devices 110. In other embodiments, however, the media playback system 100 omits the group 107a and/or other grouped arrangements of the playback devices 110.

The media playback system 100 includes the NMDs 120a and 120b, each comprising one or more microphones configured to receive voice utterances from a user. In the illustrated embodiment of FIG. 1B, the NMD 120a is a standalone device and the NMD 120b is integrated into the playback device 110n. The NMD 120a, for example, is configured to receive voice input 121 from a user 123. In some embodiments, the NMD 120a transmits data associated with the received voice input 121 to a voice assistant service (VAS) configured to (i) process the received voice input data and (ii) facilitate one or more operations on behalf of the media playback system 100.

In some aspects, for example, the computing device 106c comprises one or more modules and/or servers of a VAS (e.g., a VAS operated by one or more of SONOS, AMAZON, GOOGLE APPLE, MICROSOFT, etc.). The computing device 106c can receive the voice input data from the NMD 120a via the network 104 and the links 103.

In response to receiving the voice input data, the computing device 106c processes the voice input data (i.e., “Play Hey Jude by The Beatles”), and determines that the processed voice input includes a command to play a song (e.g., “Hey Jude”). In some embodiments, after processing the voice input, the computing device 106c accordingly transmits commands to the media playback system 100 to play back “Hey Jude” by the Beatles from a suitable media service (e.g., via one or more of the computing devices 106) on one or more of the playback devices 110. In other embodiments, the computing device 106c may be configured to interface with media services on behalf of the media playback system 100. In such embodiments, after processing the voice input, instead of the computing device 106c transmitting commands to the media playback system 100 causing the media playback system 100 to retrieve the requested media from a suitable media service, the computing device 106c itself causes a suitable media service to provide the requested media to the media playback system 100 in accordance with the user's voice utterance.

b. Suitable Playback Devices

FIG. 1C is a block diagram of the playback device 110a comprising an input/output 111. The input/output 111 can include an analog I/O 111a (e.g., one or more wires, cables, and/or other suitable communication links configured to carry analog signals) and/or a digital I/O 111b (e.g., one or more wires, cables, or other suitable communication links configured to carry digital signals). In some embodiments, the analog I/O 111a is an audio line-in input connection comprising, for example, an auto-detecting 3.5 mm audio line-in connection. In some embodiments, the digital I/O 111b comprises a Sony/Philips Digital Interface Format (S/PDIF) communication interface and/or cable and/or a Toshiba Link (TOSLINK) cable. In some embodiments, the digital I/O 111b comprises a High-Definition Multimedia Interface (HDMI) interface and/or cable. In some embodiments, the digital I/O 111b includes one or more wireless communication links comprising, for example, a radio frequency (RF), infrared, WIFI, BLUETOOTH, or another suitable communication link. In certain embodiments, the analog I/O 111a and the digital I/O 111b comprise interfaces (e.g., ports, plugs, jacks, etc.) configured to receive connectors of cables transmitting analog and digital signals, respectively, without necessarily including cables.

The playback device 110a, for example, can receive media content (e.g., audio content comprising music and/or other sounds) from a local audio source 105 via the input/output 111 (e.g., a cable, a wire, a PAN, a BLUETOOTH connection, an ad hoc wired or wireless communication network, and/or another suitable communication link). The local audio source 105 can comprise, for example, a mobile device (e.g., a smartphone, a tablet, a laptop computer, etc.) or another suitable audio component (e.g., a television, a desktop computer, an amplifier, a phonograph (such as an LP turntable), a Blu-ray player, a memory storing digital media files, etc.). In some aspects, the local audio source 105 includes local music libraries on a smartphone, a computer, a networked-attached storage (NAS), and/or another suitable device configured to store media files. In certain embodiments, one or more of the playback devices 110, NMDs 120, and/or control devices 130 comprise the local audio source 105. In other embodiments, however, the media playback system omits the local audio source 105 altogether. In some embodiments, the playback device 110a does not include an input/output 111 and receives all audio content via the network 104.

The playback device 110a further comprises electronics 112, a user interface 113 (e.g., one or more buttons, knobs, dials, touch-sensitive surfaces, displays, touchscreens, etc.), and one or more transducers 114 (referred to hereinafter as “the transducers 114”). The electronics 112 are configured to receive audio from an audio source (e.g., the local audio source 105) via the input/output 111 or one or more of the computing devices 106a-c via the network 104 (FIG. 1), amplify the received audio, and output the amplified audio for playback via one or more of the transducers 114. In some embodiments, the playback device 110a optionally includes one or more microphones 115 (e.g., a single microphone, a plurality of microphones, a microphone array) (hereinafter referred to as “the microphones 115”). In certain embodiments, for example, the playback device 110a having one or more of the optional microphones 115 can operate as an NMD configured to receive voice input from a user and correspondingly perform one or more operations based on the received voice input.

In the illustrated embodiment of FIG. 1C, the electronics 112 comprise one or more processors 112a (referred to hereinafter as “the processors 112a”), memory 112b, software components 112c, a network interface 112d, one or more audio processing components 112g (referred to hereinafter as “the audio components 112g”), one or more audio amplifiers 112h (referred to hereinafter as “the amplifiers 112h”), and power 112i (e.g., one or more power supplies, power cables, power receptacles, batteries, induction coils, Power-over Ethernet (POE) interfaces, and/or other suitable sources of electric power). In some embodiments, the electronics 112 optionally include one or more other components 112j (e.g., one or more sensors, video displays, touchscreens, battery charging bases, etc.).

The processors 112a can comprise clock-driven computing component(s) configured to process data, and the memory 112b can comprise a computer-readable medium (e.g., a tangible, non-transitory computer-readable medium loaded with one or more of the software components 112c) configured to store instructions for performing various operations and/or functions. The processors 112a are configured to execute the instructions stored on the memory 112b to perform one or more of the operations. The operations can include, for example, causing the playback device 110a to retrieve audio data from an audio source (e.g., one or more of the computing devices 106a-c (FIG. 1)), and/or another one of the playback devices 110. In some embodiments, the operations further include causing the playback device 110a to send audio data to another one of the playback devices 110a and/or another device (e.g., one of the NMDs 120). Certain embodiments include operations causing the playback device 110a to pair with another of the one or more playback devices 110 to enable a multi-channel audio environment (e.g., a stereo pair, a bonded zone, etc.).

The processors 112a can be further configured to perform operations causing the playback device 110a to synchronize playback of audio content with another of the one or more playback devices 110. As those of ordinary skill in the art will appreciate, during synchronous playback of audio content on a plurality of playback devices, a listener will preferably be unable to perceive time-delay differences between playback of the audio content by the playback device 110a and the other one or more other playback devices 110. Additional details regarding audio playback synchronization among playback devices can be found, for example, in U.S. Pat. No. 8,234,395, which is incorporated by reference above.

In some embodiments, the memory 112b is further configured to store data associated with the playback device 110a, such as one or more zones and/or zone groups of which the playback device 110a is a member, audio sources accessible to the playback device 110a, and/or a playback queue with which the playback device 110a (and/or another of the one or more playback devices) can be associated. The stored data can comprise one or more state variables that are periodically updated and used to describe a state of the playback device 110a. The memory 112b can also include data associated with a state of one or more of the other devices (e.g., the playback devices 110, NMDs 120, control devices 130) of the media playback system 100. In some aspects, for example, the state data is shared during predetermined intervals of time (e.g., every 5 seconds, every 10 seconds, every 60 seconds, etc.) among at least a portion of the devices of the media playback system 100, so that one or more of the devices have the most recent data associated with the media playback system 100.

The network interface 112d is configured to facilitate a transmission of data between the playback device 110a and one or more other devices on a data network such as, for example, the links 103 and/or the network 104 (FIG. 1). The network interface 112d is configured to transmit and receive data corresponding to media content (e.g., audio content, video content, text, photographs) and other signals (e.g., non-transitory signals) comprising digital packet data including an Internet Protocol (IP)-based source address and/or an IP-based destination address. The network interface 112d can parse the digital packet data such that the electronics 112 properly receive and process the data destined for the playback device 110a.

In the illustrated embodiment of FIG. 1C, the network interface 112d comprises one or more wireless interfaces 112e (referred to hereinafter as “the wireless interface 112e”). The wireless interface 112e (e.g., a suitable interface comprising one or more antennae) can be configured to wirelessly communicate with one or more other devices (e.g., one or more of the other playback devices 110, NMDs 120, and/or control devices 130) that are communicatively coupled to the network 104 (FIG. 1B) in accordance with a suitable wireless communication protocol (e.g., WIFI, BLUETOOTH, LTE, etc.). In some embodiments, the network interface 112d optionally includes a wired interface 112f (e.g., an interface or receptacle configured to receive a network cable such as an Ethernet, a USB-A, USB-C, and/or Thunderbolt cable) configured to communicate over a wired connection with other devices in accordance with a suitable wired communication protocol. In certain embodiments, the network interface 112d includes the wired interface 112f and excludes the wireless interface 112e. In some embodiments, the electronics 112 exclude the network interface 112d altogether and transmit and receive media content and/or other data via another communication path (e.g., the input/output 111).

The audio components 112g are configured to process and/or filter data comprising media content received by the electronics 112 (e.g., via the input/output 111 and/or the network interface 112d) to produce output audio signals. In some embodiments, the audio processing components 112g comprise, for example, one or more digital-to-analog converters (DACs), audio preprocessing components, audio enhancement components, digital signal processors (DSPs), and/or other suitable audio processing components, modules, circuits, etc. In certain embodiments, one or more of the audio processing components 112g can comprise one or more subcomponents of the processors 112a. In some embodiments, the electronics 112 omit the audio processing components 112g. In some aspects, for example, the processors 112a execute instructions stored on the memory 112b to perform audio processing operations to produce the output audio signals.

The amplifiers 112h are configured to receive and amplify the audio output signals produced by the audio processing components 112g and/or the processors 112a. The amplifiers 112h can comprise electronic devices and/or components configured to amplify audio signals to levels sufficient for driving one or more of the transducers 114. In some embodiments, for example, the amplifiers 112h include one or more switching or class-D power amplifiers. In other embodiments, however, the amplifiers 112h include one or more other types of power amplifiers (e.g., linear gain power amplifiers, class-A amplifiers, class-B amplifiers, class-AB amplifiers, class-C amplifiers, class-D amplifiers, class-E amplifiers, class-F amplifiers, class-G amplifiers, class H amplifiers, and/or another suitable type of power amplifier). In certain embodiments, the amplifiers 112h comprise a suitable combination of two or more of the foregoing types of power amplifiers. Moreover, in some embodiments, individual ones of the amplifiers 112h correspond to individual ones of the transducers 114. In other embodiments, however, the electronics 112 include a single one of the amplifiers 112h configured to output amplified audio signals to a plurality of the transducers 114. In some other embodiments, the electronics 112 omit the amplifiers 112h.

The transducers 114 (e.g., one or more speakers and/or speaker drivers) receive the amplified audio signals from the amplifier 112h and render or output the amplified audio signals as sound (e.g., audible sound waves having a frequency between about 20 Hertz (Hz) and 20 kilohertz (kHz)). In some embodiments, the transducers 114 can comprise a single transducer. In other embodiments, however, the transducers 114 comprise a plurality of audio transducers. In some embodiments, the transducers 114 comprise more than one type of transducer. For example, the transducers 114 can include one or more low frequency transducers (e.g., subwoofers, woofers), mid-range frequency transducers (e.g., mid-range transducers, mid-woofers), and one or more high frequency transducers (e.g., one or more tweeters). As used herein, “low frequency” can generally refer to audible frequencies below about 500 Hz, “mid-range frequency” can generally refer to audible frequencies between about 500 Hz and about 2 kHz, and “high frequency” can generally refer to audible frequencies above 2 kHz. In certain embodiments, however, one or more of the transducers 114 comprise transducers that do not adhere to the foregoing frequency ranges. For example, one of the transducers 114 may comprise a mid-woofer transducer configured to output sound at frequencies between about 200 Hz and about 5 kHz.

By way of illustration, Sonos, Inc. presently offers (or has offered) for sale certain playback devices including, for example, a “SONOS ONE,” “PLAY:1,” “PLAY:3,” “PLAY:5,” “PLAYBAR,” “PLAYBASE,” “CONNECT:AMP,” “CONNECT,” “AMP,” “PORT,” and “SUB.” Other suitable playback devices may additionally or alternatively be used to implement the playback devices of example embodiments disclosed herein. Additionally, one of ordinary skill in the art will appreciate that a playback device is not limited to the examples described herein or to Sonos product offerings. In some embodiments, for example, one or more playback devices 110 comprise wired or wireless headphones (e.g., over-the-ear headphones, on-ear headphones, in-ear earphones, etc.). In other embodiments, one or more of the playback devices 110 comprise a docking station and/or an interface configured to interact with a docking station for personal mobile media playback devices. In certain embodiments, a playback device may be integral to another device or component such as a television, an LP turntable, a lighting fixture, or some other device for indoor or outdoor use. In some embodiments, a playback device omits a user interface and/or one or more transducers. For example, FIG. 1D is a block diagram of a playback device 110p comprising the input/output 111 and electronics 112 without the user interface 113 or transducers 114.

FIG. 1E is a block diagram of a bonded playback device 110q comprising the playback device 110a (FIG. 1C) sonically bonded with the playback device 110i (e.g., a subwoofer) (FIG. 1A). In the illustrated embodiment, the playback devices 110a and 110i are separate ones of the playback devices 110 housed in separate enclosures. In some embodiments, however, the bonded playback device 110q comprises a single enclosure housing both the playback devices 110a and 110i. The bonded playback device 110q can be configured to process and reproduce sound differently than an unbonded playback device (e.g., the playback device 110a of FIG. 1C) and/or paired or bonded playback devices (e.g., the playback devices 110l and 110m of FIG. 1B). In some embodiments, for example, the playback device 110a is full-range playback device configured to render low frequency, mid-range frequency, and high frequency audio content, and the playback device 110i is a subwoofer configured to render low frequency audio content. In some aspects, the playback device 110a, when bonded with the first playback device, is configured to render only the mid-range and high frequency components of a particular audio content, while the playback device 110i renders the low frequency component of the particular audio content. In some embodiments, the bonded playback device 110q includes additional playback devices and/or another bonded playback device.

c. Suitable Network Microphone Devices (NMDs)

FIG. 1F is a block diagram of the NMD 120a (FIGS. 1A and 1B). The NMD 120a includes one or more voice processing components 124 (hereinafter “the voice components 124”) and several components described with respect to the playback device 110a (FIG. 1C) including the processors 112a, the memory 112b, and the microphones 115. The NMD 120a optionally comprises other components also included in the playback device 110a (FIG. 1C), such as the user interface 113 and/or the transducers 114. In some embodiments, the NMD 120a is configured as a media playback device (e.g., one or more of the playback devices 110), and further includes, for example, one or more of the audio components 112g (FIG. 1C), the amplifiers 112h, and/or other playback device components. In certain embodiments, the NMD 120a comprises an Internet of Things (IoT) device such as, for example, a thermostat, alarm panel, fire and/or smoke detector, etc. In some embodiments, the NMD 120a comprises the microphones 115, the voice processing components 124, and only a portion of the components of the electronics 112 described above with respect to FIG. 1C. In some aspects, for example, the NMD 120a includes the processor 112a and the memory 112b (FIG. 1C), while omitting one or more other components of the electronics 112. In some embodiments, the NMD 120a includes additional components (e.g., one or more sensors, cameras, thermometers, barometers, hygrometers, etc.).

In some embodiments, an NMD can be integrated into a playback device. FIG. 1G is a block diagram of a playback device 110r comprising an NMD 120d. The playback device 110r can comprise many or all of the components of the playback device 110a and further include the microphones 115 and voice processing components 124 (FIG. 1F). The playback device 110r optionally includes an integrated control device 130c. The control device 130c can comprise, for example, a user interface (e.g., the user interface 113 of FIG. 1C) configured to receive user input (e.g., touch input, voice input, etc.) without a separate control device. In other embodiments, however, the playback device 110r receives commands from another control device (e.g., the control device 130a of FIG. 1B).

Referring again to FIG. 1F, the microphones 115 are configured to acquire, capture, and/or receive sound from an environment (e.g., the environment 101 of FIG. 1A) and/or a room in which the NMD 120a is positioned. The received sound can include, for example, vocal utterances, audio played back by the NMD 120a and/or another playback device, background voices, ambient sounds, etc. The microphones 115 convert the received sound into electrical signals to produce microphone data. The voice processing components 124 receive and analyze the microphone data to determine whether a voice input is present in the microphone data. The voice input can comprise, for example, an activation word followed by an utterance including a user request. As those of ordinary skill in the art will appreciate, an activation word is a word or other audio cue signifying a user voice input. For instance, in querying the AMAZON VAS, a user might speak the activation word “Alexa.” Other examples include “Ok, Google” for invoking the GOOGLE VAS and “Hey, Siri” for invoking the APPLE VAS.

After detecting the activation word, voice processing components 124 monitor the microphone data for an accompanying user request in the voice input. The user request may include, for example, a command to control a third-party device, such as a thermostat (e.g., NEST thermostat), an illumination device (e.g., a PHILIPS HUE lighting device), or a media playback device (e.g., a SONOS playback device). For example, a user might speak the activation word “Alexa” followed by the utterance “set the thermostat to 68 degrees” to set a temperature in a home (e.g., the environment 101 of FIG. 1A). The user might speak the same activation word followed by the utterance “turn on the living room” to turn on illumination devices in a living room area of the home. The user may similarly speak an activation word followed by a request to play a particular song, an album, or a playlist of music on a playback device in the home.

d. Suitable Control Devices

FIG. 1H is a partial schematic diagram of the control device 130a (FIGS. 1A and 1B). As used herein, the term “control device” can be used interchangeably with “controller” or “control system.” Among other features, the control device 130a is configured to receive user input related to the media playback system 100 and, in response, cause one or more devices in the media playback system 100 to perform an action(s) or operation(s) corresponding to the user input. In the illustrated embodiment, the control device 130a comprises a smartphone (e.g., an iPhone™, an Android phone, etc.) on which media playback system controller application software is installed. In some embodiments, the control device 130a comprises, for example, a tablet (e.g., an iPad™), a computer (e.g., a laptop computer, a desktop computer, etc.), and/or another suitable device (e.g., a television, an automobile audio head unit, an IoT device, etc.). In certain embodiments, the control device 130a comprises a dedicated controller for the media playback system 100. In other embodiments, as described above with respect to FIG. 1G, the control device 130a is integrated into another device in the media playback system 100 (e.g., one more of the playback devices 110, NMDs 120, and/or other suitable devices configured to communicate over a network).

The control device 130a includes electronics 132, a user interface 133, one or more speakers 134, and one or more microphones 135. The electronics 132 comprise one or more processors 132a (referred to hereinafter as “the processors 132a”), a memory 132b, software components 132c, and a network interface 132d. The processor 132a can be configured to perform functions relevant to facilitating user access, control, and configuration of the media playback system 100. The memory 132b can comprise data storage that can be loaded with one or more of the software components executable by the processor 132a to perform those functions. The software components 132c can comprise applications and/or other executable software configured to facilitate control of the media playback system 100. The memory 132b can be configured to store, for example, the software components 132c, media playback system controller application software, and/or other data associated with the media playback system 100 and the user.

The network interface 132d is configured to facilitate network communications between the control device 130a and one or more other devices in the media playback system 100, and/or one or more remote devices. In some embodiments, the network interface 132d is configured to operate according to one or more suitable communication industry standards (e.g., infrared, radio, wired standards including IEEE 802.3, wireless standards including IEEE 802.11a, 802.11b, 802.11g, 802.11n, 802.11ac, 802.15, 4G, LTE, etc.). The network interface 132d can be configured, for example, to transmit data to and/or receive data from the playback devices 110, the NMDs 120, other ones of the control devices 130, one of the computing devices 106 of FIG. 1, devices comprising one or more other media playback systems, etc. The transmitted and/or received data can include, for example, playback device control commands, state variables, playback zone and/or zone group configurations. For instance, based on user input received at the user interface 133, the network interface 132d can transmit a playback device control command (e.g., volume control, audio playback control, audio content selection, etc.) from the control device 130a to one or more of the playback devices 110. The network interface 132d can also transmit and/or receive configuration changes such as, for example, adding/removing one or more playback devices 110 to/from a zone, adding/removing one or more zones to/from a zone group, forming a bonded or consolidated player, separating one or more playback devices from a bonded or consolidated player, among others.

The user interface 133 is configured to receive user input and can facilitate control of the media playback system 100. The user interface 133 includes media content art 133a (e.g., album art, lyrics, videos, etc.), a playback status indicator 133b (e.g., an elapsed and/or remaining time indicator), media content information region 133c, a playback control region 133d, and a zone indicator 133e. The media content information region 133c can include a display of relevant information (e.g., title, artist, album, genre, release year, etc.) about media content currently playing and/or media content in a queue or playlist. The playback control region 133d can include selectable (e.g., via touch input and/or via a cursor or another suitable selector) icons to cause one or more playback devices in a selected playback zone or zone group to perform playback actions such as, for example, play or pause, fast forward, rewind, skip to next, skip to previous, enter/exit shuffle mode, enter/exit repeat mode, enter/exit cross fade mode, etc. The playback control region 133d may also include selectable icons to modify equalization settings, playback volume, and/or other suitable playback actions. In the illustrated embodiment, the user interface 133 comprises a display presented on a touch screen interface of a smartphone (e.g., an iPhone™, an Android phone, etc.). In some embodiments, however, user interfaces of varying formats, styles, and interactive sequences may alternatively be implemented on one or more network devices to provide comparable control access to a media playback system.

The one or more speakers 134 (e.g., one or more transducers) can be configured to output sound to the user of the control device 130a. In some embodiments, the one or more speakers comprise individual transducers configured to correspondingly output low frequencies, mid-range frequencies, and/or high frequencies. In some aspects, for example, the control device 130a is configured as a playback device (e.g., one of the playback devices 110). Similarly, in some embodiments the control device 130a is configured as an NMD (e.g., one of the NMDs 120), receiving voice commands and other sounds via the one or more microphones 135.

The one or more microphones 135 can comprise, for example, one or more condenser microphones, electret condenser microphones, dynamic microphones, and/or other suitable types of microphones or transducers. In some embodiments, two or more of the microphones 135 are arranged to capture location information of an audio source (e.g., voice, audible sound, etc.) and/or configured to facilitate filtering of background noise. Moreover, in certain embodiments, the control device 130a is configured to operate as a playback device and an NMD. In other embodiments, however, the control device 130a omits the one or more speakers 134 and/or the one or more microphones 135. For instance, the control device 130a may comprise a device (e.g., a thermostat, an IoT device, a network device, etc.) comprising a portion of the electronics 132 and the user interface 133 (e.g., a touch screen) without any speakers or microphones.

### III. PoE Playback Device Discussion

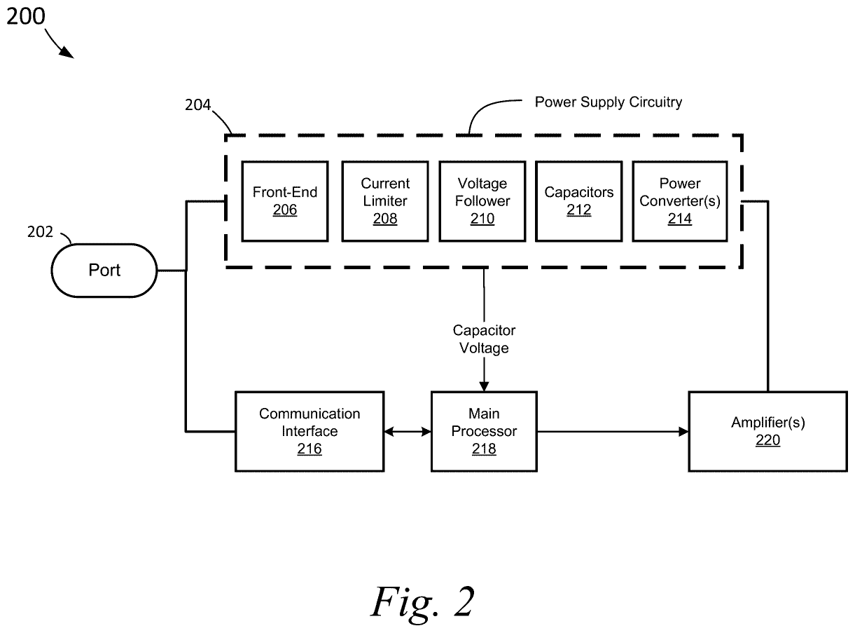

According to various embodiments, playback devices 110 such as those described herein above can be configured to receive both audio data and line power via a powered communication port, such as a power over Ethernet (PoE) port, for example. As described herein, the playback device generally includes one or more amplifiers (e.g., amplifiers 112h) configured to drive one or more speakers (e.g., transducers 114) to provide an audio output. In such examples where the playback device is configured to receive power over a combined power/communication line such as an Ethernet cable or a USB cable, power supply circuitry can be used to provide conditioned power for supplying the one or more amplifiers with adequate input power to output undistorted audio via an output device such as the one or more speakers. FIG. 2 illustrates a sample schematic of power and signal processing circuitry 200 including one or more bulk capacitors configured to provide uninterrupted power to an amplifier for providing non-distorted audio output as described herein. The power and signal processing circuitry 200 may be included in a playback device, such as described above, that includes one or more speakers and is configured to play back audio data to produce the audio output from the one or more speakers.

As shown in FIG. 2, circuitry 200 can include an input port 202. As described herein, the input port 202 can be configured to receive both power and data via a single cable such as an Ethernet or USB cable. The circuitry 200 can further include power supply circuitry 204. As shown in FIG. 2, the power supply circuitry 204 can include a front-end circuit 206, a current limiter 208, a voltage follower 210, one or more capacitors 212, and one or more power converter(s) 214. However, it should be noted that the components as shown as being included within power supply circuitry 204 are shown by way of example only, and in certain implementations, additional or fewer components can be included within the power supply circuitry 204.

As further shown in FIG. 2, circuitry 200 can further include a communication interface 216, one or more processor(s) 218, and one or more amplifiers 220. As such, the arrangement of circuitry 200 includes a power processing path that includes the power supply circuitry 204 and a data processing path that includes the communication interface 216 and the processor(s) 218. Both the power processing path and the data processing path can converge at the amplifier(s) 220. Additionally, as shown in FIG. 2, and as discussed further below, the power supply circuitry 204 can be configured to condition the power received from the input port 202 to provide power to the amplifier(s) 220.

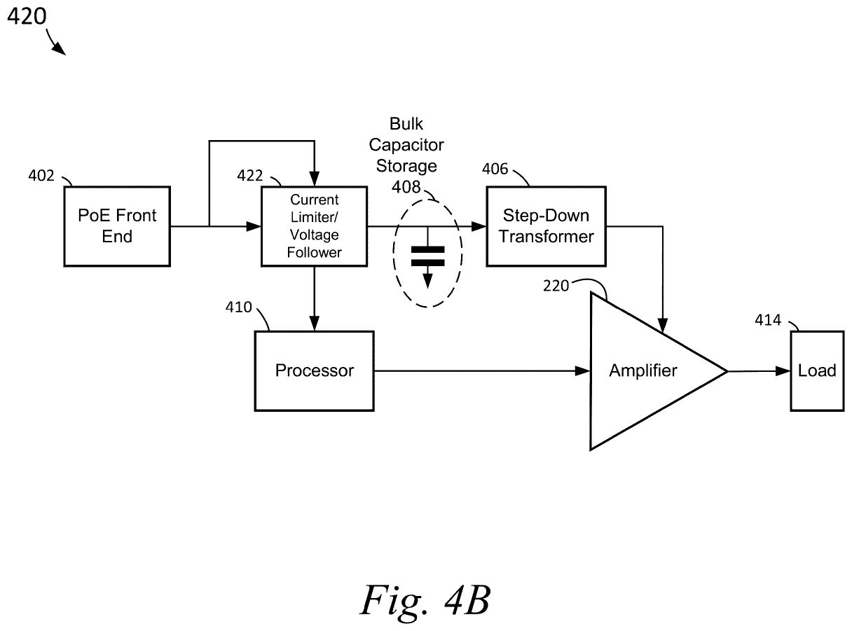

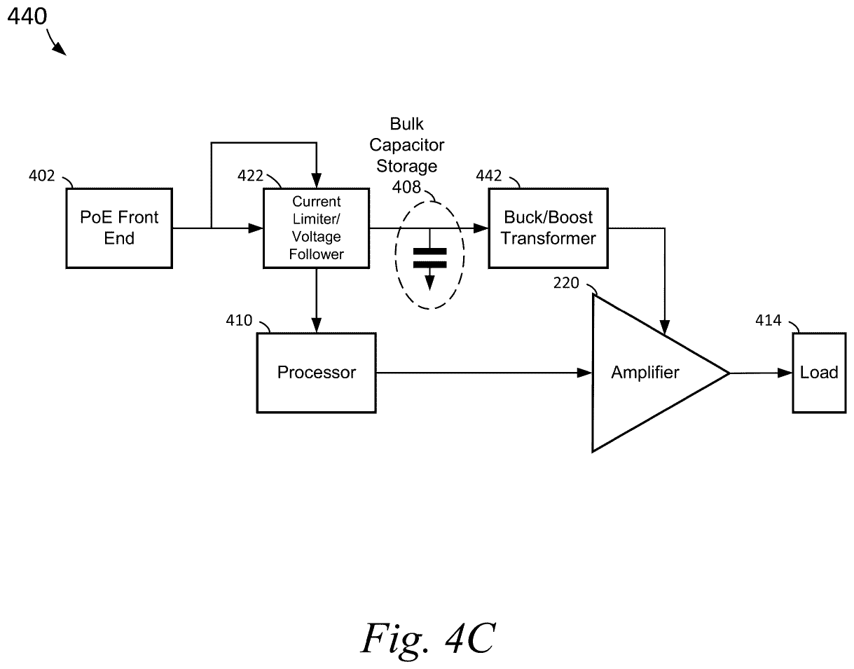

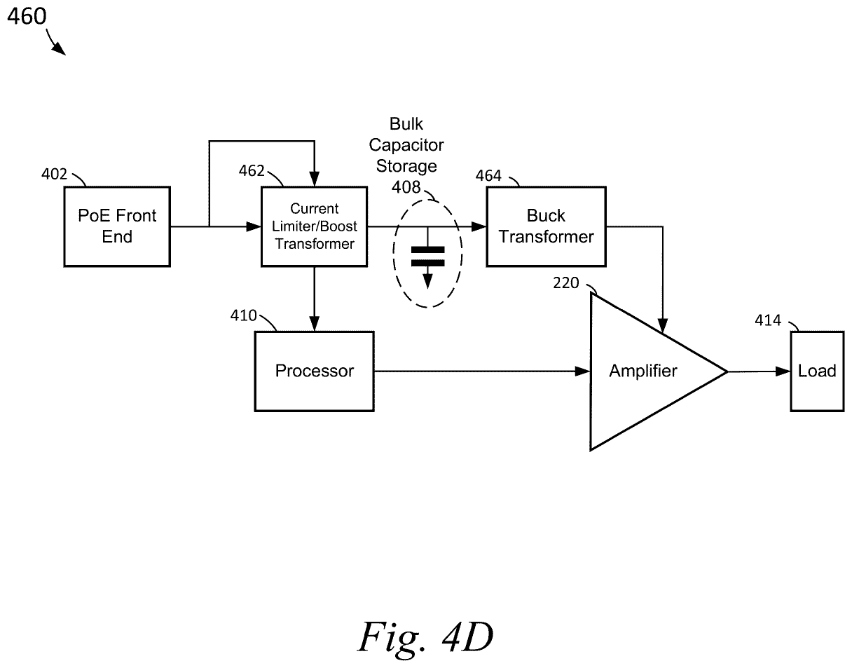

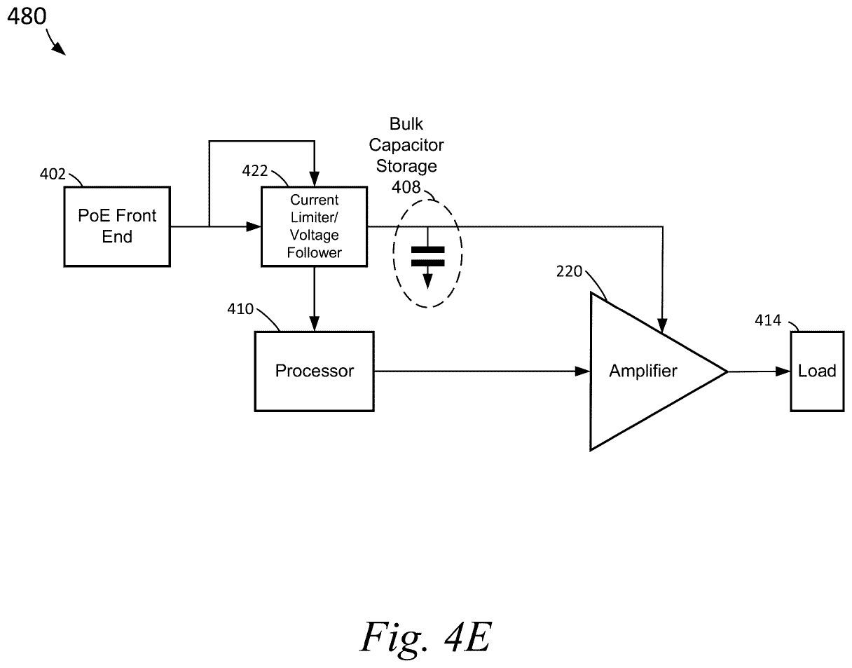

More specifically, according to certain embodiments, the power supply circuitry 204 can be configured to use the available voltage received from the input port 202 to increase the available power provided to the amplifier(s) 220 (e.g., beyond the power available to the circuitry 200 via the input port 202). In certain implementations, the power supply circuitry 204 can be configured to provide a boosted wattage to the amplifier(s) 220 by appropriately charging and discharging the one or more capacitors 212, as discussed further below. The power supply circuitry 204 can be configured to leverage the fact that in certain circumstances, the voltage received from the input port 202 and output from the front-end circuit 206 exceeds the steady-state voltage needed to operate the amplifier(s) 220. Accordingly, in such an example, the power supply circuitry 204 can be configured to use the excess voltage available from the front-end circuit 206 to appropriately charge the one or more capacitors 212 such that, when additional power is needed at the amplifier(s) 220, the capacitors 212 can be discharged, thereby providing a power boost to the input of the amplifier(s) 220. Such an arrangement provides for limited distortion of the output audio as powered by the amplifier(s) 220 and as further described herein below. Additional examples of specific power supply circuitry implementations can be found in FIGS. 4A-4E and the accompanying descriptions as included below.

In some examples, the one or more capacitors 212 can be configured such that they discharge at least 50% of their stored energy, thereby providing a power boost to the amplifier(s) 220. However, the total energy discharged by the capacitors 212 can vary based upon the overall circuitry design and available power at the input port 202. For example, if the circuitry 200 is a PoE circuit, the available power at the input port 202 can be in a range of about 40-60 volts DC, for example, 41-57 volts; however, the operational voltage of the amplifier(s) 220 may be approximately 24 volts. As such, the input voltage at the one or more capacitors 212 can be allowed to vary between, for example, 57 volts and 24 volts while still providing the expected 24 volts to the amplifier 220. Working those values for the maximum voltage (57 Volts) and the minimum voltage (24 Volts) through Function (F3) above, the usable energy in the one or more capacitors 212 is 82%. In other words, the one or more capacitors 212 can provide an energy discharge of approximately 82% of total energy storage. As such, in certain implementations, the one or more capacitors 212 used for bulk capacitor storage as described herein can be configured to discharge between about 50% and about 85% of total energy stored to provide for a power boost to the amplifier(s) 220.

According to certain embodiments, the current limiter 208 and voltage follower 210 can be configured to monitor the current drawn from the front-end circuit 206 and ensure that the current remains below a predetermined limit to avoid any overload conditions. For instance, the current limiter 208 may limit the current draw through the front-end circuit 206 (and/or the port 202) to a particular value during conditions where the power demand (e.g., by the amplifier(s) 220) exceeds the limits of the front-end circuit 206 and the one or more capacitors 212 are being discharged. This advantageously mitigates the possibility of the front-end circuit 206 malfunctioning because of a current draw that exceeds the capability of the front-end circuit 206 during periods of high power demand.

In addition, the voltage follower 210 may provide a bypass path to the power converter(s) 214 when the current is not approaching the limit, so as to avoid unnecessary loss. The power converter(s) 214 may be configured to condition and appropriately set the level of the voltage supplied to the amplifier(s) 220 such that the amplifier(s) 220 consistently receive the correct operating voltage. For example, as discussed further below, the power converter(s) 214 may include a step-down converter to reduce the voltage from the front-end circuit 206 (which may be in a range of 41-57 volts in some examples, as discussed above) to the set operating voltage of the amplifier(s) 220 (which may be approximately 24 volts in some examples).

The processor(s) 218 may comprise one or more processors that execute program instructions that cause the circuitry 200 and/or a device into which the circuitry 200 is implemented to perform one or more operations. The program instructions may be stored in memory (e.g., the memory 112b) that comprises one or more memory devices (e.g., non-volatile memory devices and/or volatile memory devices). In some implementations, the program instructions executed by the processor(s) 218 may cause the circuitry 200 to monitor a capacitor voltage across the capacitors 212 and take appropriate action when the capacitor voltage is too low (e.g., indicating that the capacitor(s) 212 are nearing that maximum discharge level). For instance, one or more parameters associated with playback of audio content (e.g., volume, equalization settings, etc.) may be modified to reduce power consumption (e.g., of the amplifiers) when the capacitor voltage falls below one or more thresholds. As a result, the power consumption of the amplifier(s) 220 (and/or any device that the circuitry 200 is incorporated into) may be kept below the maximum power rating for the port 202 and/or the front-end circuit 206 when the capacitor(s) 212 have been discharged without interrupting audio playback or causing the device to malfunction (e.g., reboot, turn off, etc.).

Additionally (or alternatively), the processor(s) 218 may execute program instructions that cause the circuitry 200 (and/or a device, such as a playback device, that the circuitry 200 is incorporated into) to perform any of the operations described herein including, for example, synchronous playback of audio content with other playback devices.

It should be appreciated that the processor(s) 218 may be implemented in any of a variety of ways. In some instances, the processor(s) 218 may be implemented using a plurality of processors that are distributed across multiple integrated circuits (ICs). For example, the circuitry 200 may comprise a power management integrated circuit (PMIC) including at least one processor and a main system-on-a-chip (SoC) that also includes at least one processor. In this example, the PMIC may read the capacitor voltage and provide information to the main SoC that includes an indication of the capacitor voltage (or some derivative thereof). The main SoC may, in turn, modify how audio is played back using the amplifier(s) 220 based on the information from the PMIC. For instance, the main SoC may reduce the volume (and/or change one or more equalization settings) when the capacitor voltage is getting low to reduce the power consumption of the amplifier(s) 220 (e.g., so as not exceed the power capability of the port 202 when the capacitor(s) 212 are fully discharged). In other examples, processor(s) 218 may be implemented as a single processor in a single SoC or multiple processor(s) in a single SoC. Accordingly, the processor(s) 218 may be implemented in any of a variety of ways using any of a variety of ICs.

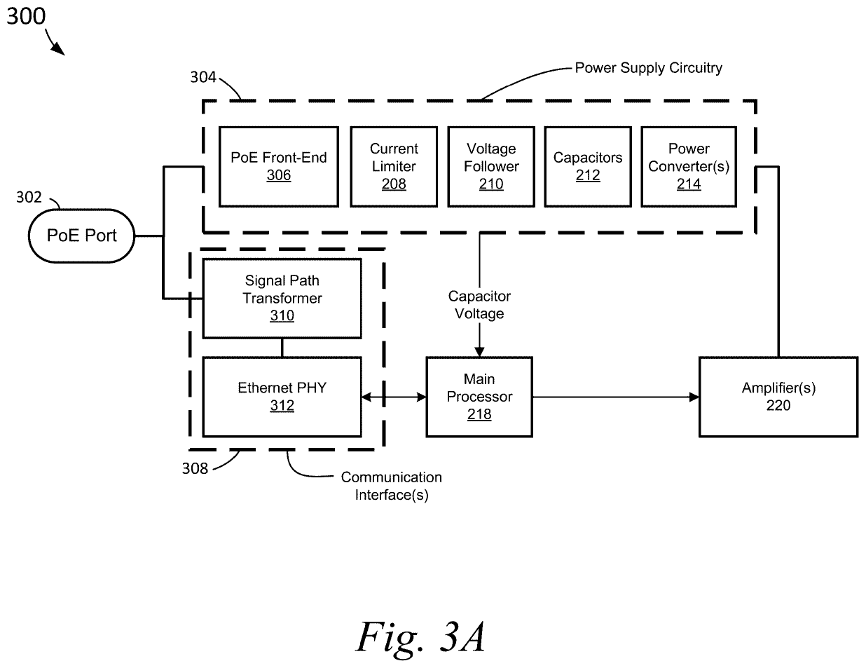

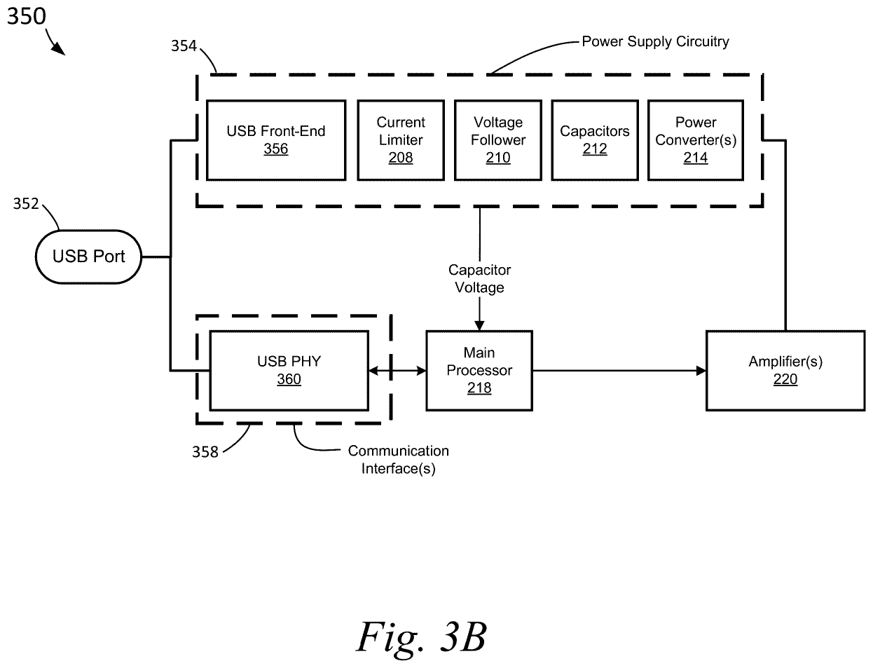

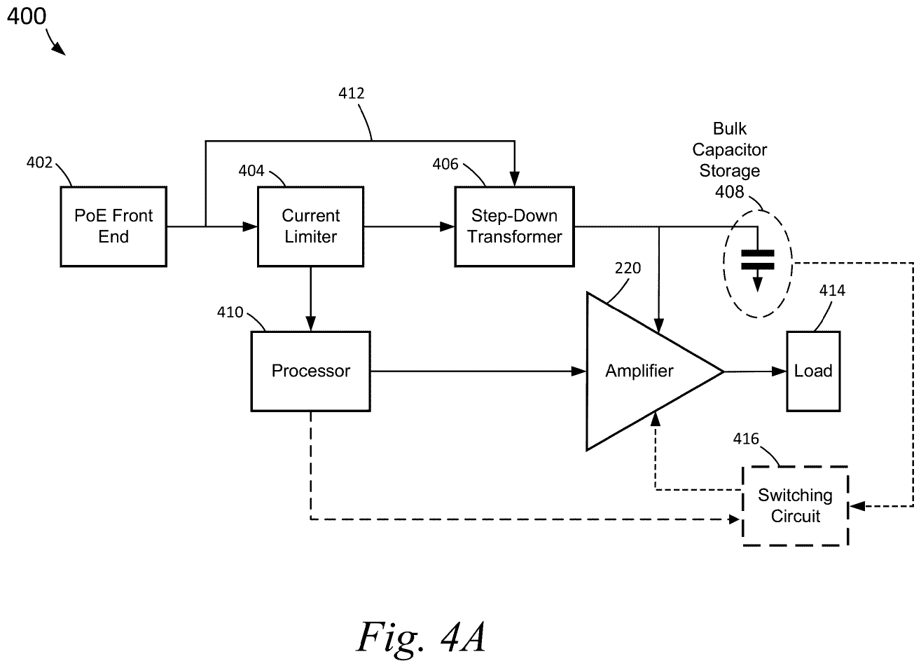

As described herein, power for an audio playback device can be received via a combination power and data cable. For example, the cable can be either an Ethernet or a USB cable as described above. While most of the examples as described herein are directed towards PoE, similar power supply circuitry can be used to condition power as received over a USB cable for providing power to an amplifier of a playback device as described herein. For example, FIGS. 3A and 3B illustrate a PoE power example and a USB power example respectively.

As shown in FIG. 3A, according to certain embodiments, circuitry 300 includes a PoE port 302 configured to receive both power and data via an Ethernet cable. The circuitry 300 further includes power supply circuitry 304. As shown in FIG. 3A, the power supply circuitry 304 can include a PoE front-end circuit 306, a current limiter 208, a voltage follower 210, one or more capacitors 212, and one or more power converters 214. Additionally, as further shown in FIG. 3A, the circuitry 300 can include a communication interface 308. The communication interface 308 can include a signal path transformer 310 configured to isolate the data path to/from the PoE power 302 from the power injected into the PoE cable via a PoE injector. The communication interface 308 may further comprise an Ethernet physical layer processor 312 that facilitates communication with external devices via the PoE port 302. The communication interface 308 can be operably connected to the processor(s) 218. The processor(s) 218 be configured to perform (e.g., execute program instructions that cause) digital signal processing on data received from the communication interface 308 to produce a processed audio data stream. The power supply circuitry 304 can be configured to provide conditioned power to the amplifier(s) 220. Similarly, the processor(s) 218 can be configured to provide a digital signal to the amplifier(s) 220 including the processed audio data stream to be amplified by the amplifier(s) 220 and output to an output device such as a speaker as described herein.

Similarly, as shown in FIG. 3B, according to certain embodiments, circuitry 350 includes a USB port 352 configured to receive both power and data via a USB cable. The circuitry 350 further includes power supply circuitry 354. As shown in FIG. 3B, the power supply circuitry 354 can include a USB front-end circuit 356, a current limiter 208, a voltage follower 210, one or more capacitors 212, and one or more power converters 214. Additionally, as further shown in FIG. 3B, the circuitry 350 can include a communication interface 358. The communication interface 358 can include a USB physical layer processor 360. The communication interface 358 can be operably connected to the processor(s) 218 configured to perform digital signal processing on data received from the communication interface to produce a processed audio data stream. The power supply circuitry 354 can be configured to provide conditioned power to the amplifier(s) 220, as discussed above. Similarly, the processor 218 can be configured to provide a digital signal to the amplifier(s) 220 including the processed audio data stream to be amplified by the amplifier(s) 220 and output to an output device such as a speaker as described herein.

The power supply circuitry as described herein can include various designs for receiving and conditioning power as received from a PoE port 302, for example (or from a USB port 352), for providing input power to an audio amplifier as described herein. FIGS. 4A-4E illustrate various design options for circuitry that includes power supply circuitry as described herein and which may be implemented in an audio playback device. To limit the number of components as shown in the figures, the examples as shown in FIGS. 4A-4E are generally directed towards the power supply circuitry and related components rather than the data processing components as described above. It will be appreciated, given the benefit of this disclosure, that examples of the power supply circuitry may include various other components (e.g., capacitors, resistors, switches, converters, and/or other electronic components) not shown in FIGS. 4A-4E.

FIG. 4A illustrates a sample circuitry 400 in which power supply circuitry includes both a current limiter 404 and a step-down converter 406. The circuitry 400 further includes a PoE front-end 402, bulk capacitor storage 408, an amplifier 220 that drives a load 414 (such as a speaker, for example), and a processor 410. The PoE front-end 402 can be configured to receive both power and data from a single Ethernet cable as described above. As shown in FIG. 4A, the power output as processed by the PoE front-end 402 can be directed, via the current limiter 404, to the step-down converter 406. In certain examples, the current limiter 404 corresponds to the current limiter 208 discussed above with reference to FIGS. 2, 3A, and 3B. As described herein, the current limiter 404 can be configured to include a hardware fail-safe to limit the line power as pulled by the power supply circuitry from the PoE front-end 402 to a level below the maximum available current. For example, a PoE power supply can be limited to approximately 2 amps of current. In such an example, the current limiter 404 can be configured to limit the line power (e.g., drawn current) to a level below the available maximum current. In certain examples, the current limiter 404 may be configured to provide a bypass path 412 to the step-down converter 406 in conditions where the current drawn from the PoE front-end 402 is below the set limit to reduce loss. For example, the current limiter 404 may be implemented as a MOSFET that is in an open condition (providing the bypass path 412) unless the current limit is being approached. Additionally, in some examples, the current limiter 404 can be programmable such that one or more processors can be configured to recognize the type of the powered communication port operably connected to the current limiter 404 and program the current limiter 404 to limit the line power drawn to a level at or below the maximum current available (as determined based upon the type of powered communication port connected to the current limiter). In such an example, the current limiter 404 can be configured to include both gain control circuitry and level shift control circuitry to provide for the current limiting functionality.

As further shown in FIG. 4A, the output of the current limiter 404 can be directed to the step-down converter 406. The step-down converter 406 can be configured to provide an output voltage that is lower than the input voltage as received from the current limiter 404. For example, if the voltage of the signal output from the PoE front-end 402 is 57 volts, the voltage of the signal output from the current limiter 404 may also be approximately 57 volts. However, as discussed above, in certain examples, the operational voltage of the amplifier 220 may be significantly less than 57 volts, for example, 24 volts or in a range of 12-24 volts. Accordingly, the step-down converter 406 can be configured to step down the 57 volts to an appropriate voltage for the audio amplifier such as, for example, 12-24 volts. In certain examples, the step-down converter 406 may correspond to, or be a part of, the power converter 214 discussed above with reference to FIGS. 2, 3A, and 3B. Additionally, the step-down converter 406 can be operatively connected to the bulk capacitor storage 408. In such an example, the bulk capacitor storage 408 can be configured to store energy from the power as output by the step-down converter 406 until needed to boost the power to the amplifier 220. In certain examples, the bulk capacitor storage may include a bank of one or more capacitors coupled together in series and/or parallel. In some examples, the bulk capacitor storage 408 corresponds to, or is a part of, the capacitors 212 discussed above with reference to FIGS. 2, 3A, and 3B.

As described herein, the amplifier 220 drives the load 414, which in certain examples may be an audio output device such as a speaker for an audio playback device in which the circuitry 400 is implemented. The processor 410 can be configured to process a received audio signal (e.g., from the communication interfaces 216, 308, or 358) to output a digital audio stream for amplification by the amplifier 220, the amplified digital audio stream then being provided to the load 414 to produce an audio output. In some examples, the processor 410 may correspond to, or be a part of, the processor(s) 218 discussed above with reference to FIGS. 2, 3A, and 3B. In certain examples, the processor 410 can be configured to control the current limiter 404 to prevent overload conditions as discussed above. Furthermore, the processor 410 can be configured to monitor the bulk capacitor storage 408 to determine the available energy contained within the capacitors, as well as to control one or more switching circuits 416 for turning on and off the bulk capacitor storage 408 to the amplifier 220, thereby controlling power boost to the amplifier 220 as needed to provide a steady output and undistorted audio stream to the load 414. In certain examples, the processor 410 can be configured to control the amplifier 220 to modulate the volume of the audio output (and therefore the power requirements of the amplifier 220) based on the available power (e.g., the voltage or power level output from the PoE front-end 402 and/or the available energy stored in the bulk capacitor storage 408) to prevent or reduce any distortion in the audio output. In certain examples, the circuitry 400 can be configured to provide a steady conditioned power level of at least 60 Watts of the available to the amplifier 220 for driving the load 414 during play back of audio data. In certain examples, the processor 410 includes, or is coupled to, at least one non-transitory computer-readable medium that stores program instructions executable by the processor to control a playback device in which the circuitry 400 is implemented to play back the audio data, wherein to play back includes supplying the amplifier 220 with the conditioned power based on the audio data.

Thus, FIG. 4A presents an example of one implementation of power supply circuitry that can use the bulk capacitor storage 408 to provide temporary, on-demand power boosts to the amplifier 220 as may be needed to accommodate increased peak power demands during certain audio playback or other conditions. Additional examples and implementations are discussed below with reference to FIGS. 4B-4E.

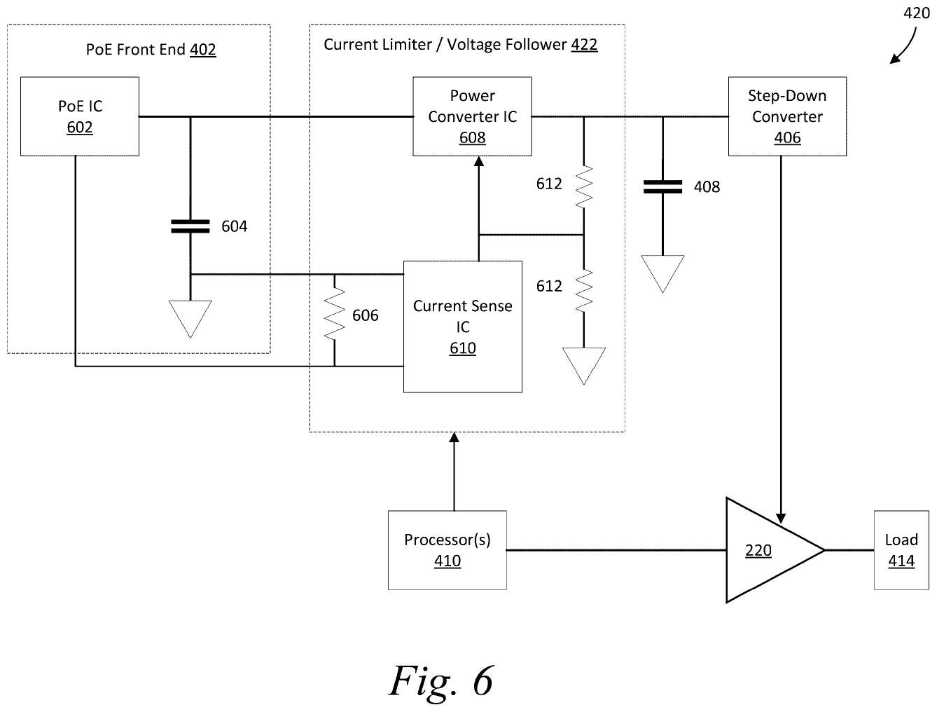

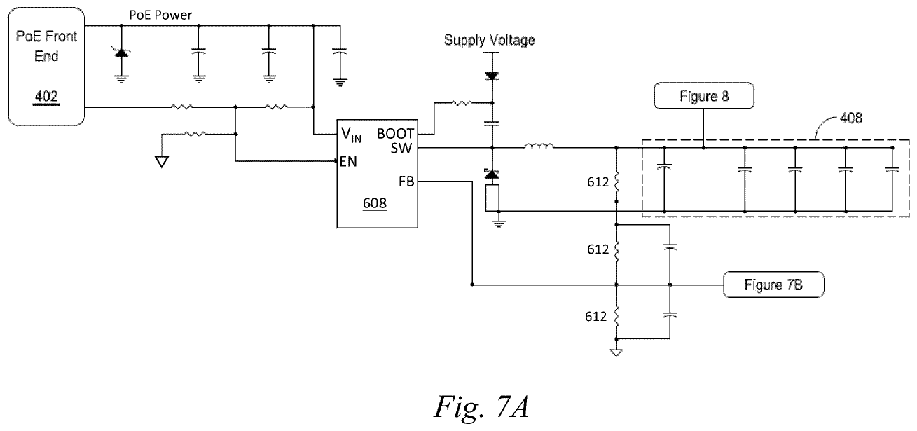

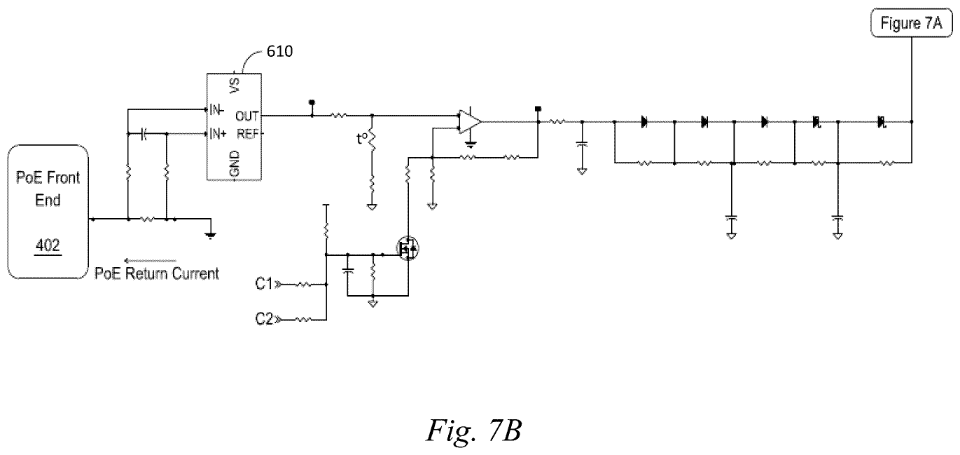

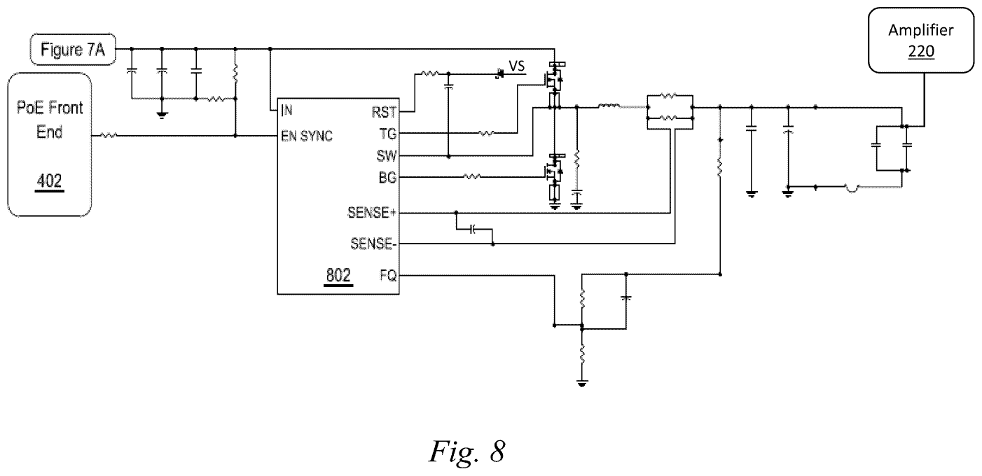

Referring to FIG. 4B, there is illustrated a sample circuitry 420 in which power supply circuitry includes both a current limiter/voltage follower circuit 422 and a step-down converter 406. In certain examples, the current limiter/voltage follower circuit 422 corresponds to the current limiter 208 and voltage follower 210 discussed above with reference to FIGS. 2, 3A, and 3B. The circuitry 420 further includes the PoE front-end 402, processor 410, and amplifier 220 driving the load 414, similar to the arrangement discussed above with reference to FIG. 4A. FIG. 6 illustrates a schematic diagram of an example of the circuitry 420. FIGS. 7A, 7B, and 8 are circuit diagrams illustrating an example implementation of a portion of the circuitry 420 of FIGS. 4B and 6.

Referring to FIGS. 4B, 6, 7A, 7B, and 8, the power output as processed by the PoE front-end 402 can be directed to the current limiter/voltage follower circuit 422. The current limiter portion of the current limiter/voltage follower circuit 422 may operate in a manner similar to the current limiter 404 discussed above with reference to FIG. 4A. As shown in FIG. 6, the current limiter/voltage follower circuit 422 may include a power converter integrated circuit (IC) 608 and a current sense IC 610. The current sense IC 610 measures a current through a current sense impedance 606. The current flowing through the current sense impedance 606 is received from the PoE front-end 402 via a front-end capacitor 604. An output from the current sense IC 610 is provided to the power converter IC 608. The output of the current sense IC 610 is also coupled to the output of the power converter IC 608 via a voltage divider formed by a plurality of feedback impedances 612. In circuit examples, control signals C1, C2 may be applied, as shown in FIG. 7B, to control at least some of the operation of the current limiter/voltage follower circuit 422.

The output of the current limiter/voltage follower circuit 422 may have the same voltage as the input to the circuit through operation of the voltage follower portion of the circuit. For example, if the voltage at the output of the PoE front-end 402 is 57 volts, the voltage at the output of the current limiter/voltage follower circuit 424 will also be 57 volts. This output can be directed the bulk capacitor storage 408 (as shown in FIGS. 4B, 6, and 7A) for charging of the capacitors contained therein, as discussed above. Additionally, the output of the current limiter/voltage follower circuit 424 can be directed to the step-down converter 406. In one example of this configuration, the step-down converter 406 can receive power at 57 volts and can be configured to step down the 57 volts to an appropriate voltage for the audio amplifier 220 such as, for example, 24 volts. As shown in FIG. 8, in some examples, the step-down converter 406 may include a power converter IC 802 and associated circuitry to perform the step-down conversion. In the example of FIGS. 4B, 6, 7A, 7B, and 8, by positioning the bulk capacitor storage 408 before the step-down converter 406, the full available voltage from the PoE front-end 402 (e.g., 57 volts) can be used to provide energy for charging the capacitors. Any voltage lost due to impedance added to the circuit 420 by the bulk capacitor storage 408 can be compensated for by the step-down converter 406 which is configured to provide a steady voltage output for the amplifier 220 (e.g., 24 volts).

As described herein, the processor 410 can be configured to process a received audio signal to output a digital audio stream for amplification by the amplifier 220. As discussed above, during certain playback situations (e.g., at high volume for certain tracks) the peak power demands to drive the load 414 may considerably exceed the input power available from the PoE front-end 402. In such circumstances, the bulk capacitor storage 408 can be discharged to supply a power boost to the amplifier 220 to meet the increased peak power demands and avoid distortion of the audio output from the load 414. During other operating conditions, when the power demands are lower and within the capabilities of the PoE front-end 402, the voltage differential between the output of the PoE front-end 402 and the input voltage requirement of the amplifier 220 (e.g., the difference between 57 volts and 24 volts) can be used to charge the bulk capacitor storage 408 as discussed above. Because the bulk capacitor storage 408 can be charged across the relatively wide voltage range that is available between the output of the PoE front-end 402 and the input to the amplifier 220 without causing the input voltage to the amplifier 220 to drop too low (which could introduce distortion into the audio output from the load 414), the usable energy that can be discharged from the bulk capacitor storage 408 is substantially increased and therefore smaller capacitors can be used to achieve the desired usable energy. This provides a significant advantage in volume-constrained devices, such as some audio playback devices.

According to certain embodiments, the processor 410 can be configured to, monitor the bulk capacitor storage 408 to determine the available energy contained within the capacitors, as well as control one or more switching circuits for turning on and off the bulk capacitor storage 408 to the amplifier 220, thereby controlling power boost to the amplifier 220 as needed to provide a steady output and undistorted audio stream to the load 414, as discussed above. Although not shown in FIG. 4B, in certain examples, the processor 410 may include (or be operatively coupled to) a comparator and/or an analog-to-digital converter (ADC) to measure the voltage at the bulk capacitor storage 408 and trigger the processor 410 to reduce the power demand (e.g., by changing volume of playback) should the voltage across the bulk capacitor storage drop below a predetermined threshold (e.g., 25 volts in the examples in which the operational voltage of the amplifier 220 is 24 volts). Additionally, in certain examples, the processor 410 can be configured to control the current limiter/voltage follower circuit 424.

FIG. 4C illustrates a sample circuitry 440 in which the power supply circuitry includes both the current limiter/voltage follower circuit 422 and a buck/boost converter 442. In certain examples, the buck/boost converter 442 may correspond to, or be part of, the power converter 214 discussed above with reference to FIGS. 2, 3A, and 3B. As shown in FIG. 4C, the circuitry 440 further includes a PoE front-end 402, bulk capacitor storage 408, processor 410, and amplifier 220 driving the load 414. As further shown in FIG. 4C, the power output as processed by the PoE front-end 402 can be directed to the current limiter/voltage follower circuit 422, and the output from the current limiter/voltage follower circuit can be directed to the bulk capacitor storage 408 for charging of the capacitors contained therein, as discussed above. Additionally, the output of the current limiter/voltage follower circuit 422 can be directed to the buck/boost converter 442. As described herein, a buck/boost converter can be configured to both reduce (buck) an input voltage to a particular level as well as raise (boost) an input voltage to a particular level. In this example, the buck/boost converter 442 can receive power and condition the power to provide to the amplifier 220. As described above, the amplifier 220 may require a steady input of 24 volts. As such, the buck/boost converter 442 can be configured to receive power from the current limiter/voltage follower circuit 422 and either reduce or raise the voltage to the appropriate level. In such an example, the impedance associated with the bulk capacitor storage 408 can be such that the overall available voltage to the buck/boost converter 442 drops below the needed voltage for the amplifier 220. Such an arrangement can provide for quicker charging of the capacitors contained within the bulk capacitor storage 408.

FIG. 4D illustrates a sample circuitry 460 that includes both a current limiter/boost converter 462 and a buck converter 464, along with the PoE front-end 402, bulk capacitor storage 408, processor 410, and amplifier 220 driving the load 414. As further shown in FIG. 4D, the power output as processed by the PoE front-end 402 can be directed to the current limiter/boost converter 462. Unlike circuits 400, 420, and 440 as described above, the output of the current limiter/boost converter circuit 462 can have a higher output voltage than input voltage. For example, the input voltage to the current limiter/boost converter circuit 462 can be 57 volts as described above. The boost converter portion of the circuit 462 can boost the voltage to, for example, about 150 volts. This output can be directed the bulk capacitor storage 408 for charging of the capacitors contained therein. Additionally, the output of the current limiter/boost converter circuit 462 can be directed to a buck converter 464. The buck converter 464 can be configured to reduce the input voltage for providing to the amplifier 220 as described herein. For example, the buck converter 464 can be configured to reduce the 150 volts as output by the current limiter/boost converter circuit 462 to 24 volts to meet the operational voltage requirements of the amplifier 220. Such an arrangement including a boosted voltage to the bulk capacitor storage 408 can provide for quicker charging of the capacitors contained within the bulk capacitor storage 408 while still providing for the required steady voltage as required by the amplifier 220 via the buck converter 464. In certain examples, the processor 410 can be configured to control the current limiter/boost converter circuit 462 along with its other functions as described herein.

FIG. 4E illustrates a sample circuitry 480 in which the amplifier 220 is a high voltage amplifier. In this example, unlike circuits 400, 420, 440, and 460, no additional voltage conditioning components are included in circuit 480. Rather, by carefully selecting the capacitance values in the bulk capacitor storage 408, the input voltage to an amplifier can be controlled.

As described above, the output of the current limiter/voltage follower circuit 422 will have the same voltage as the input to the circuit from the PoE front-end 402. For example, the input voltage to the current limiter/voltage follower circuit 422 can be 57 volts as described above. As such, the output of the current limiter/voltage follower circuit 422 will also be 57 volts. This output can be directed the bulk capacitor storage 408 for charging of the capacitors contained therein, as discussed above. Additionally, the output of the current limiter/voltage follower circuit 422 can be directed to the amplifier 220. As such, in such an arrangement, the overall capacitance (and associated impedance) of the bulk capacitor storage 408 is selected such that the line voltage to the amplifier 220 is at an appropriate level for powering the amplifier (e.g., 24 volts as described herein). Such an arrangement including a higher voltage to the bulk capacitor storage 408 can provide for quicker charging of the capacitors contained within the bulk capacitor storage 408 while still providing for the required steady voltage required by an amplifier. However, while the overall number of components in the circuit 480 can be reduced, the overall design complexity of the circuit may be increased to ensure that the voltage as provided to the amplifier 220 is properly conditioned (e.g., at an appropriate voltage) via the impedance provided by the bulk capacitor storage 408.

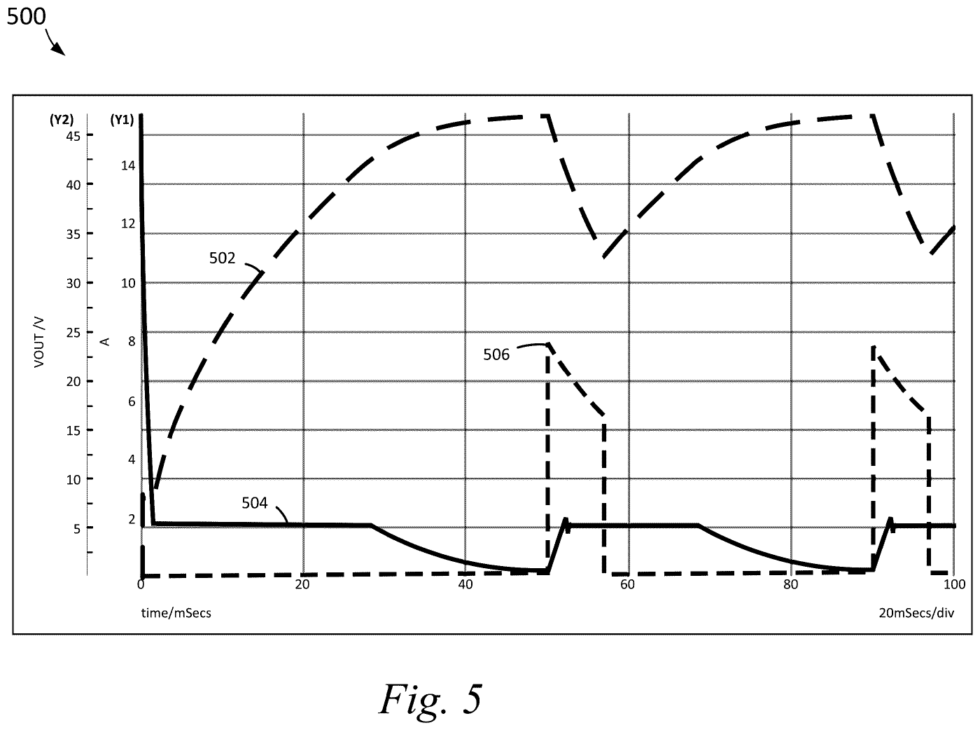

FIG. 5 illustrates a sample output graph 500 from a simulation of a power supply circuit as described herein. For example, the output is shown in FIG. 5 can be generated using a power supply circuit such as circuit 420 as shown in FIG. 4B and described above, wherein the power supply circuit includes both a current limiter and a step-down converter. As shown in graph 500, line 502 represents the immediate voltage bus representing the voltage available as input to the stepdown converter. Line 504 represents the input current available from the PoE front-end 402. line 506 represents the load current or the output current from the operational amplifier 220 that is provided to the load 414 such as a speaker as described herein.

As shown in the graph 500, as line 502 increases, the current as drawn from the PoE front-end 402 decreases, however, when the current to the load spikes (as shown around time 50) on line 506 and the bus voltage drops (indicating a discharge event by the bulk capacitor storage 408), the input current increases to recharge the capacitors. Once the bulk capacitor storage 408 is recharged (represented by line 502 reaching its peak and flattening), the input current again drops until another load spike on the input current (e.g., around time 90) on line 506. As such, as shown by the output of the simulation, when excess power is required by the amplifier 220 to provide a higher output load current (represented by the spikes in line 506), the bulk capacitor storage 408 discharges (represented by the drops in line 502) to provide the needed power boost. Similarly, to recharge the capacitors, the input current increases (represented by the climbs in line 504) until the bulk capacitor storage 408 reaches its steady state.

### IV. Conclusion

The above discussions relating to playback devices, controller devices, playback zone configurations, and media content sources provide only some examples of operating environments within which functions and methods described herein may be implemented. Other operating environments and configurations of media playback systems, playback devices, and network devices not explicitly described herein may also be applicable and suitable for implementation of the functions and methods. For example, embodiments of the power supply circuitry as described herein can be used in any powered playback device where the available input power is limited such that the power to the amplifier may be under the amplifiers requirements resulting in audio distortion.

The description above discloses, among other things, various example systems, methods, apparatus, and articles of manufacture including, among other components, firmware and/or software executed on hardware. It is understood that such examples are merely illustrative and should not be considered as limiting. For example, it is contemplated that any or all of the firmware, hardware, and/or software aspects or components can be embodied exclusively in hardware, exclusively in software, exclusively in firmware, or in any combination of hardware, software, and/or firmware. Accordingly, the examples provided are not the only ways to implement such systems, methods, apparatus, and/or articles of manufacture.

Additionally, references herein to “embodiment” means that a particular feature, structure, or characteristic described in connection with the embodiment can be included in at least one example embodiment of an invention. The appearances of this phrase in various places in the specification are not necessarily all referring to the same embodiment, nor are separate or alternative embodiments mutually exclusive of other embodiments. As such, the embodiments described herein, explicitly and implicitly understood by one skilled in the art, can be combined with other embodiments.

The specification is presented largely in terms of illustrative environments, systems, procedures, steps, logic blocks, processing, and other symbolic representations that directly or indirectly resemble the operations of data processing devices coupled to networks. These process descriptions and representations are typically used by those skilled in the art to most effectively convey the substance of their work to others skilled in the art. Numerous specific details are set forth to provide a thorough understanding of the present disclosure. However, it is understood to those skilled in the art that certain embodiments of the present disclosure can be practiced without certain, specific details. In other instances, well known methods, procedures, components, and circuitry have not been described in detail to avoid unnecessarily obscuring aspects of the embodiments. Accordingly, the scope of the present disclosure is defined by the appended claims rather than the foregoing description of embodiments.

When any of the appended claims are read to cover a purely software and/or firmware implementation, at least one of the elements in at least one example is hereby expressly defined to include a tangible, non-transitory medium such as a memory, DVD, CD, Blu-ray, and so on, storing the software and/or firmware.

### V. Examples

(Example 1) A playback device comprising: at least one powered communication port configured to receive audio data and line power, the line power being limited to a maximum power and a maximum current; one or more amplifiers configured to drive one or more speakers, the one or more amplifiers being operable to consume conditioned power and having a peak power consumption that is greater than the maximum power of the line power; power supply circuitry comprising at least one capacitor, the power supply circuitry configured to receive the line power, charge the at least one capacitor to store energy, supply the conditioned power at least in part by discharging 50% or more of the energy stored in the at least one capacitor, and limit a current draw of the power supply circuitry to a level that is no more than the maximum current of the line power; at least one communication interface configured to facilitate communication via the at least one powered communication port; at least one processor coupled to the at least one communication interface and the one or more amplifiers; and at least one non-transitory computer-readable medium coupled to the at least one processor and storing program instructions executable by the at least one processor to control the playback device to play back at least a portion of the audio data, wherein to play back comprises to supply the one or more amplifiers with the conditioned power based on the portion of the audio data.

(Example 2) The playback device of Example 1, wherein the power supply circuitry comprises switch circuitry configured to charge or discharge the at least one capacitor based on the conditioned power consumed by the one or more amplifiers.

(Example 3) The playback device of Example 2, wherein the power supply circuitry is coupled with the at least one powered communication port and the one or more amplifiers.

(Example 4) The playback device of Example 3, wherein the power supply circuitry comprises current limiting circuitry coupled to the at least one powered communication port and the at least one processor.

(Example 5) The playback device of Example 4, wherein the current limiting circuitry comprises a hardware fail-safe to limit the line power to the maximum current.

(Example 6) The playback device of Example 5, wherein the current limiting circuitry is programmable and the program instructions are executable by the at least one processor to: recognize a type of the powered communication port; and program the current limiting circuitry to limit the line power to the maximum current based on the type of the powered communication port.

(Example 7) The playback device of Example 6, wherein the current limiting circuitry comprises gain control circuitry and level shift control circuitry.

(Example 8) The playback device of Example 7, wherein the at least one powered communication port comprises a power over Ethernet (PoE) port.

(Example 9) The playback device of Example 8, wherein the at least one capacitor is coupled to the one or more amplifiers and coupled with the PoE port via the current limiting circuitry.

(Example 10) The playback device of Example 9, wherein the power supply circuitry comprises at least one voltage follower circuit.

(Example 11) The playback device of Example 10, wherein the power supply circuitry further comprises a step-down converter coupled to the current limiting circuitry, wherein the at least one capacitor is coupled with the PoE port via the step-down converter and the current limiting circuitry.

(Example 12) The playback device of Example 8, wherein the power supply circuitry comprises a converter coupled to the one or more amplifiers, wherein the at least one capacitor is coupled with the at least one PoE port via the current limiting circuitry and the one or more amplifiers via the converter.

(Example 13) The playback device of Example 12, wherein the power supply circuitry comprises at least one voltage follower circuit and the converter comprises a step-down converter.

(Example 14) The playback device of Example 12, wherein the power supply circuitry comprises at least one voltage follower circuit and the converter comprises a buck-boost converter.

(Example 15) The playback device of Example 12, wherein the power supply circuitry comprises at least one boost circuit and the converter comprises a buck converter.

(Example 16) The playback device of any one of Examples 1-15, wherein to play back comprises to: generate an audio signal from the audio data; and modulate the audio signal based on conditioned power available from the power supply.

(Example 17) The playback device of Example 16, wherein the power supply circuitry further comprises a comparator coupled to the at least one capacitor, the comparator being configured to: communicate a control signal to the at least one processor if voltage at the at least one capacitor transgresses a threshold value; and modulate comprises to adjust an amplitude of the audio signal based on the control signal.

(Example 18) The playback device of any one of Examples 1-17, wherein the at least one powered communication port comprises one or more of a power over Ethernet (PoE) port and a universal serial bus (USB) port.

(Example 19) The playback device of any one of Examples 1-18, wherein the playback device is configured to make at least 60 Watts of the conditioned power available to the one or more amplifiers during play back of the audio data.

(Example 20) The playback device of any one of Examples 1-19, wherein the one or more amplifiers are operable to consume up to 170 Watts of the conditioned power during play back of the portion of the audio data.

(Example 21) A playback device comprising: at least one powered communication port configured to receive audio data and line power, the line power having a first voltage and being limited to a maximum power and a maximum current; one or more amplifiers configured to drive one or more speakers, the one or more amplifiers being operable to consume conditioned power at a second voltage that is lower than the first voltage and having a peak power consumption that is greater than the maximum power of the line power; power supply circuitry comprising at least one capacitor, the power supply configured to receive the line power, charge the at least one capacitor, supply the conditioned power at least in part by allowing a voltage across the at least one capacitor to vary between the first voltage and the second voltage, and limit a current draw of the power supply circuitry to a level that is no more than the maximum current of the line power; at least one communication interface configured to facilitate communication via the at least one powered communication port; at least one processor coupled to the at least one communication interface and the one or more amplifiers; and at least one non-transitory computer-readable medium coupled to the at least one processor and storing program instructions executable by the at least one processor to control the playback device to play back at least a portion of the audio data, wherein to play back comprises to supply the one or more amplifiers with the conditioned power based on the portion of the audio data.

(Example 22) The playback device of Example 21, wherein the power supply circuitry comprises switch circuitry configured to charge or discharge the at least one capacitor based on the conditioned power consumed by the one or more amplifiers.

(Example 23) The playback device of Example 22, wherein the power supply circuitry is coupled with the at least one powered communication port and the one or more amplifiers.

(Example 24) The playback device of Example 23, wherein the power supply circuitry comprises current limiting circuitry coupled to the at least one powered communication port and the at least one processor.

(Example 25) The playback device of Example 24, wherein the current limiting circuitry comprises a hardware fail-safe to limit the line power to the maximum current.

(Example 26) The playback device of Example 25, wherein the current limiting circuitry is programmable and the program instructions are executable by the at least one processor to: recognize a type of the powered communication port; and program the current limiting circuitry to limit the line power to the maximum current based on the type of the powered communication port.

(Example 27) The playback device of Example 26, wherein the current limiting circuitry comprises gain control circuitry and level shift control circuitry.

(Example 28) The playback device of Example 27, wherein the at least one powered communication port comprises a power over Ethernet (PoE) port.

(Example 29) The playback device of Example 28, wherein the at least one capacitor is coupled to the one or more amplifiers and coupled with the PoE port via the current limiting circuitry.

(Example 30) The playback device of Example 29, wherein the power supply circuitry comprises at least one voltage follower circuit.

(Example 31) The playback device of Example 30, wherein the power supply circuitry further comprises a step-down converter coupled to the current limiting circuitry, wherein the at least one capacitor is coupled with the PoE port via the step-down converter and the current limiting circuitry.

(Example 32) The playback device of Example 28, wherein the power supply circuitry comprises a converter coupled to the one or more amplifiers, wherein the at least one capacitor is coupled with the at least one PoE port via the current limiting circuitry and the one or more amplifiers via the converter.

(Example 33) The playback device of Example 32, wherein the power supply circuitry comprises at least one voltage follower circuit and the converter comprises a step-down converter.

(Example 34) The playback device of Example 32, wherein the power supply circuitry comprises at least one voltage follower circuit and the converter comprises a buck-boost converter.

(Example 35) The playback device of Example 32, wherein the power supply circuitry comprises at least one boost circuit and the converter comprises a buck converter.

(Example 36) A method of operating a playback device, the method comprising: receiving audio content and line power via at least one powered communication port of the playback device, the line power having a line voltage and being limited to a maximum power and a maximum current; playing back, using one or more amplifiers of the playback device, the audio content received via the at least one powered communication port, the one or more amplifiers having a peak power consumption that is higher than the maximum power of the line power; providing, using power supply circuitry of the playback device, conditioned power to the one or more amplifiers based on the line power while playing back the audio content, wherein providing the conditioned power to the one or more amplifiers comprises: charging at least one capacitor of the playback device to store energy during a first period where a power consumption of the one or more amplifiers is less than the maximum power of the line power; discharging 50% or more of the energy stored in the at least one capacitor during a second period where the power consumption of the one or more amplifiers is higher than the maximum power of the line power; and limiting a current draw of the power supply circuitry to a level that is no higher than the maximum current of the line power.

(Example 37) The method of Example 36, wherein discharging 50% or more of the energy stored in the at least one capacitor comprises: discharging 75% or more of the energy stored in the at least one capacitor during the second period.

(Example 38) The method of Example 36, wherein charging at least one capacitor of the playback device comprises increasing a voltage across the at least one capacitor to a first voltage and wherein discharging 50% or more of the energy stored in the at least one capacitor comprises: allowing a voltage across the at least one capacitor to fall to a second voltage that is no higher than 75% of the first voltage.

(Example 39) The method of Example 36, wherein providing the conditioned power to the one or more amplifiers further comprises: monitoring a voltage across the at least one capacitor; detecting that the voltage across the at least one capacitor has fallen below a threshold; and modifying playback of the audio content to reduce power consumption of the one or more amplifiers.

(Example 40) The method of Example 39, wherein modifying playback of the audio content to reduce the power consumption comprises: modifying at least one of audio parameter used for playback of the audio content, where the at least one audio parameter comprises at least one of: a volume setting or an equalization setting.

(Example 41) A playback device configured to implement the method of any one of Examples 36-40.

(Example 42) A playback device comprising at least one powered communication port configured to receive audio data and line power, one or more amplifiers configured to drive one or more speakers, the one or more amplifiers having a peak power consumption that is greater than a maximum power of the line power, and power supply circuitry comprising at least one capacitor, the power supply circuitry configured to, based on a power demand of the amplifier being lower than the maximum power of the line power, cause the at least one capacitor to store energy from the line power, and based on a power demand of the one or more amplifiers exceeding the maximum power of the line power, supply conditioned power to the one or more amplifiers at least in part by at least one of discharging at least a portion of the energy stored in the at least one capacitor, and allowing a voltage across the at least one capacitor to vary between a voltage of the line power and a voltage at which power is consumed by the one or more amplifiers.

(Example 43) The playback device of Example 42, wherein supplying conditioned power comprises discharging at least 50% of the energy stored in the at least one capacitor.

(Example 44) The playback device of Example 42, further comprising at least one communication interface configured to facilitate communication via the at least one powered communication port, and at least one processor coupled to the at least one communication interface and configured to cause the playback device to play back, via the one or more amplifiers, at least a portion of the audio data.

(Example 45) The playback device of any one of Examples 42-44, wherein the power supply circuitry comprises switch circuitry configured to cause the at least one capacitor to store energy or to discharge energy stored in the at least one capacitor based on the conditioned power consumed by the one or more amplifiers.

(Example 46) The playback device of Example 44 alone or in combination with any one of Examples 42, 43, or 45, wherein the power supply circuitry is coupled with the at least one powered communication port and the one or more amplifiers.

(Example 47) The playback device of any one of Examples 42-46, wherein the power supply circuitry further comprises at least one voltage follower circuit.

(Example 48) The playback device of any one of Examples 42-47, wherein the power supply circuitry further comprises current limiting circuitry configured for limiting a current draw of the power supply circuitry to a level that is not more than a maximum current of the line power.

(Example 49) The playback device of Example 48, wherein the current limiting circuitry comprises a hardware fail-safe to limit the line power to the maximum current.

(Example 50) The playback device of one of Examples 48 or 49, wherein the at least one processor is configured to recognize a type of the powered communication port, and cause the current limiting circuitry to limit the line power to the maximum current based on the type of the powered communication port.

(Example 51) The playback device of any one of Examples 48-50, wherein the current limiting circuitry comprises gain control circuitry and level shift control circuitry.

(Example 52) The playback device of at least Example 48, wherein the at least one capacitor is coupled to the one or more amplifiers and coupled with the powered communication port via the current limiting circuitry.

(Example 53) The playback device of at least Example 48, wherein the power supply circuitry further comprises a step-down converter coupled to the current limiting circuitry, wherein the at least one capacitor is coupled with the powered communication port via the step-down converter and the current limiting circuitry.

(Example 54) The playback device of any one of Examples 48-52, wherein the power supply circuitry further comprises a converter coupled to the one or more amplifiers, wherein the at least one capacitor is coupled with the at least one powered communication port via the current limiting circuitry and to the one or more amplifiers via the converter.

(Example 55) The playback device of Example 54, wherein the power supply circuitry comprises at least one voltage follower circuit and the converter comprises one of a step-down converter, and a buck-boost converter.

(Example 56) The playback device of Example 54, wherein the power supply circuitry comprises at least one boost circuit and the converter comprises a buck converter.

(Example 57) The playback device of any one of Examples 42-56, wherein causing the playback device to play back at least the portion of the audio content comprises generating an audio signal from the audio data, and modulating the audio signal based on conditioned power available from the power supply.

(Example 58) The playback device of Example 57, wherein the power supply circuitry further comprises a comparator coupled to the at least one capacitor, the comparator being configured to communicate a control signal to the at least one processor if voltage at the at least one capacitor transgresses a threshold value, and wherein the processor is configured to adjust an amplitude of the audio signal based on the control signal.

(Example 59) The playback device of any one of Examples 42-58, wherein at least one of: the playback device is configured to make at least 60 Watts of the conditioned power available to the one or more amplifiers during play back of the audio data, and the one or more amplifiers are operable to consume up to 170 Watts of the conditioned power during play back of the portion of the audio data.

(Example 60) The playback device of any one of Examples 42-59, wherein the at least one powered communication port comprises one or more of a power over Ethernet (PoE) port and a universal serial bus (USB) port.

(Example 61) A method of operating a playback device, the method comprising receiving, via at least one powered communication port of the playback device, audio content and line power, the line power having a line voltage, playing back, using one or more amplifiers of the playback device, the audio content received via the at least one powered communication port, the one or more amplifiers having a peak power consumption that is higher than a maximum power of the line power, and providing, using power supply circuitry of the playback device, conditioned power to the one or more amplifiers based on the line power while playing back the audio content, wherein providing the conditioned power to the one or more amplifiers comprises charging at least one capacitor of the playback device to store energy during a first period in which a power consumption of the one or more amplifiers is less than the maximum power of the line power, and during a second period where the power consumption of the one or more amplifiers is higher than the maximum power of the line power, discharging at least a portion of the energy stored in the at least one capacitor.

(Example 62) The method of Example 61, further comprising, during the second period in which the power consumption of the one or more amplifiers is higher than the maximum power of the line power, limiting a current draw of the power supply circuitry to a level that is no higher than the maximum current of the line power.

(Example 63) The method of Example 62, wherein discharging at least a portion of the energy stored in the at least one capacitor comprises discharging at least 50% of the energy stored in the at least one capacitor during the second period.

(Example 64) The method of any one of Examples 61-63, wherein charging at least one capacitor of the playback device comprises increasing a voltage across the at least one capacitor to a first voltage and wherein discharging at least a portion of the energy stored in the at least one capacitor comprises allowing a voltage across the at least one capacitor to fall to a second voltage that is no higher than 75% of the first voltage.

(Example 65) The method of any one of Examples 61-64, wherein providing the conditioned power to the one or more amplifiers further comprises monitoring a voltage across the at least one capacitor, detecting that the voltage across the at least one capacitor has fallen below a threshold, and modifying playback of the audio content to reduce power consumption of the one or more amplifiers.

(Example 66) The method of Example 65, wherein modifying playback of the audio content to reduce the power consumption comprises modifying at least one of audio parameter used for playback of the audio content, where the at least one audio parameter comprises at least one of: a volume setting or an equalization setting.

1. A playback device comprising:
at least one powered communication port configured to receive audio data and line power;
at least one communication interface configured to facilitate communication via the at least one powered communication port;
one or more amplifiers configured to drive one or more speakers, the one or more amplifiers having a peak power consumption that is greater than a maximum power of the line power;
at least one processor coupled to the at least one communication interface and configured to cause the playback device to play back, via the one or more amplifiers, at least a portion of the audio data; and
power supply circuitry comprising at least one capacitor and current limiting circuitry configured to limit a current draw of the power supply circuitry to a level that is not more than a maximum current of the line power, the at least one capacitor coupled to the one or more amplifiers and coupled with the powered communication port via the current limiting circuitry, the power supply circuitry configured to:
based on a power demand of the amplifier being lower than the maximum power of the line power, cause the at least one capacitor to store energy from the line power; and
based on a power demand of the one or more amplifiers exceeding the maximum power of the line power, supply conditioned power to the one or more amplifiers at least in part by at least one of:
discharging at least a portion of the energy stored in the at least one capacitor; and
allowing a voltage across the at least one capacitor to vary between a voltage of the line power and a voltage at which power is consumed by the one or more amplifiers.

2. The playback device of claim 1, wherein supplying conditioned power comprises discharging at least 50% of the energy stored in the at least one capacitor.

3. (canceled)

4. The playback device of claim 1, wherein the power supply circuitry comprises switch circuitry configured to cause the at least one capacitor to store energy or to discharge energy stored in the at least one capacitor based on the conditioned power consumed by the one or more amplifiers.

5. The playback device of claim 1, wherein the power supply circuitry is coupled with the at least one powered communication port and the one or more amplifiers.

6. The playback device of any preceding claim, wherein the power supply circuitry further comprises at least one voltage follower circuit.

7. (canceled)

8. The playback device of claim 1, wherein the current limiting circuitry comprises a hardware fail-safe to limit the line power to the maximum current.

9. The playback device of claim 1, wherein the at least one processor is configured to:
recognize a type of the powered communication port; and
cause the current limiting circuitry to limit the line power to the maximum current based on the type of the powered communication port.

10. The playback device of claim 1, wherein the current limiting circuitry comprises gain control circuitry and level shift control circuitry.

11. (canceled)

12. The playback device of claim 1, wherein the power supply circuitry further comprises a step-down converter coupled to the current limiting circuitry, wherein the at least one capacitor is coupled with the powered communication port via the step-down converter and the current limiting circuitry.

13. The playback device of claim 1, wherein the power supply circuitry further comprises a converter coupled to the one or more amplifiers, wherein the at least one capacitor is coupled with the at least one powered communication port via the current limiting circuitry and to the one or more amplifiers via the converter.

14. The playback device of claim 13, wherein the power supply circuitry comprises at least one voltage follower circuit and the converter comprises one of:
a step-down converter; and
a buck-boost converter.

15. (canceled)

16. The playback device of claim 1, wherein causing the playback device to play back at least the portion of the audio content comprises:
generating an audio signal from the audio data; and
modulating the audio signal based on conditioned power available from the power supply.

17. The playback device of claim 16, wherein the power supply circuitry further comprises a comparator coupled to the at least one capacitor, the comparator being configured to communicate a control signal to the at least one processor if voltage at the at least one capacitor transgresses a threshold value; and
wherein the at least one processor is configured to adjust an amplitude of the audio signal based on the control signal.

18. (canceled)

19. The playback device of claim 1, wherein the at least one powered communication port comprises one or more of a power over Ethernet (PoE) port and a universal serial bus (USB) port.

20. A method of operating a playback device, the method comprising:
receiving, via at least one powered communication port of the playback device, audio content and line power, the line power having a line voltage;
playing back, using one or more amplifiers of the playback device, the audio content received via the at least one powered communication port, the one or more amplifiers having a peak power consumption that is higher than a maximum power of the line power; and
providing, using power supply circuitry of the playback device, conditioned power to the one or more amplifiers based on the line power while playing back the audio content, wherein providing the conditioned power to the one or more amplifiers comprises:
charging at least one capacitor of the playback device to store energy during a first period in which a power consumption of the one or more amplifiers is less than the maximum power of the line power; and
during a second period where the power consumption of the one or more amplifiers is higher than the maximum power of the line power, discharging at least a portion of the energy stored in the at least one capacitor.

21. The method of claim 20, further comprising:
during the second period in which the power consumption of the one or more amplifiers is higher than the maximum power of the line power, limiting a current draw of the power supply circuitry to a level that is no higher than the maximum current of the line power.

22. The method of claim 21, wherein discharging at least a portion of the energy stored in the at least one capacitor comprises:
discharging at least 50% of the energy stored in the at least one capacitor during the second period.

23. The method of claim 20, wherein charging at least one capacitor of the playback device comprises increasing a voltage across the at least one capacitor to a first voltage and wherein discharging at least a portion of the energy stored in the at least one capacitor comprises:
allowing a voltage across the at least one capacitor to fall to a second voltage that is no higher than 75% of the first voltage.

24. The method of claim 20, wherein providing the conditioned power to the one or more amplifiers further comprises:
monitoring a voltage across the at least one capacitor;
detecting that the voltage across the at least one capacitor has fallen below a threshold; and
modifying playback of the audio content to reduce power consumption of the one or more amplifiers.

25. The method of claim 24, wherein modifying playback of the audio content to reduce the power consumption comprises:
modifying at least one of audio parameter used for playback of the audio content, where the at least one audio parameter comprises at least one of: a volume setting or an equalization setting.
